(19) United States
(12) Patent Application Publication
(10) Pub. No.: US 2014/0379298 A1
(43) Pub. Date: Dec. 25, 2014

(54) Systems and Methods for Monitoring Energy Usage via Thermostat-Centered Approaches and Deriving Building Climate Analytics

(71) Applicant: Apogee Interactive, Inc., Tucker, GA (US)

(72) Inventor: Joel Stanley GILBERT, Stone Mountain, GA (US)

(21) Appl. No.: 14/304,039

(22) Filed: Jun. 13, 2014

Related U.S. Application Data
(60) Provisional application No. 61/838,033, filed on Jun. 21, 2013.

(51) Int. Cl. G01R 21/133; G01K 13/00; G01R 21/02

(52) U.S. Cl. CPC G01R 21/133; G01R 21/02; G01K 13/00
USPC 702/182

(57) ABSTRACT

A system and methods for capturing the time and temperature at which a thermostat(s) in a home turns on and turns off, and then analyzing those times and temperatures at particular granularities to identify improvements in energy usage. These time and temperature data points are some of the information needed to determine two performance attributes in the home: the ramping time when the HVAC system is returning the home to the comfort setting (which is called herein the system on time), and the ramping time for the home to hit the next on cycle.

### CROSS REFERENCE TO RELATED APPLICATION

This application claims benefit under 35 U.S.C. §119(e) and priority to U.S. Provisional Patent Application No. 61/838,033, filed Jun. 21, 2013, and entitled “Thermostat Monitoring Device and Method of Using Same”, which is incorporated herein by reference as if set forth herein in its entirety.

### TECHNICAL FIELD

The present disclosure generally relates to thermostat monitoring devices (TMDs) and methods for using the same to monitor, analyze, and interpret energy use in buildings and other thermostat-controlled structures. More particularly, the present devices and methods relate to monitoring and understanding the largest energy use (heating, cooling and water heating) in residential buildings (single and multi-family homes) and how this energy use varies with the weather and comfort decisions regarding thermostat settings.

### BACKGROUND

Smart grid concepts are convenient to the electric utilities because such utilities have only had once-a month aggregated data chunks in the billing cycles to give customers an indication of how and when they use energy, and obviously, that data is not real-time, it is past history. The specter of smart grid data, generally relates to interval meter data down to the 1-hour data and 15-minute intervals, being available would seem compelling. After all, with it, customers can be shown how their energy use varies by time-of-day and the day of the week. However, even though the data might be as recent as the day before when it is available to a customer, typically that has not shown to be more informative or motivational than monthly aggregate energy use data. Technically proficient individuals intuitively understand that comfort settings in the home will affect energy use, but even they cannot generally understand by how much.

The method presented here solves the above problems in an elegant way by monitoring the existing thermostat in the home and providing the homeowner with an intuitive summary of how that heating and/or cooling system is operating. More importantly to the utility industry, the methods presented here open up a completely new method of understanding and monitoring the performance of the home shell structure itself. Improvements in insulation and infiltration can be measured explicitly and quickly permit confirmation that weatherization efforts are effective.

### BRIEF SUMMARY OF THE DISCLOSURE

Briefly described, and according to one embodiment, aspects of the present disclosure generally relate to devices and methods for capturing the time and temperature at which a thermostat(s) in a structure (i.e., residential home, multi-family home, commercial building, et turns on and turns off, and then analyzing those times and temperatures at particular granularities to identify improvements in energy usage. These time and temperature data points are some of the useful information needed to determine two performance attributes in the structure: the ramping time when the HVAC system is returning the home to the comfort setting (which is called herein the “system on time”), and the ramping time for the home to hit the next on cycle or the “system of time”.

In one aspect, by monitoring the time and temperature data and comparing that to outside air temperatures, many attributes of the home and its HVAC system can be determined. According to one aspect, degradation over time of the HVAC system will show in trends in the on time vs. outside air temperature. Improvements in the HVAC system will lower the energy inputs to the home but the system on time may not go down and in fact might go up given the new system was sized smaller to reflect the improved insulation and air infiltration in the home. The examples (as described in greater detail below) are numerous.

In one aspect, the analysis of system off time and how the home returns to the controlled on time during these off times characterizes the shell and the internal gains in the home. In one aspect, monitoring and reporting these off times to a homeowner along with the amount of time the system(s) is on transforms thermostat understanding. For example, learning that one-degree change can reduce operating hours on the HVAC system can influence consumer behavior. Further, learning that setting the thermostat to 78° F. lowers the energy called for in the cooling system by 20-30% compared to 75° F. can be made real to customers by showing them that in their existing thermostat.

According to one embodiment, the device and methods described herein do not require the homeowner to change his/her thermostat. Instead, the device simply monitors the existing thermostat, provides intuitive information to a homeowner on his/her mobile phone and/or on a website correlating to his/her personal energy use, and helps him/her understand what he/she can do about it. In other embodiments, the present thermostat/temperature monitoring device (TMD) can replace an existing thermostat and provides the relevant information obtained via the TMD. In one embodiment, the method does not require the homeowner to attach the terminals in the TMD to the existing thermostat to produce the claimed benefits.

According to one aspect, there is provided a method for analyzing energy efficiency of a structure, comprising providing a temperature monitoring device within the structure, wherein the temperature monitoring device is capable of sensing temperature measurements according to a predetermined time interval, receiving a plurality of indoor temperature measurements associated with the interior of the structure from the temperature monitoring device for a predetermined time period at the predetermined time interval, receiving a plurality of external temperature measurements obtained from the exterior of the structure. In one aspect, the method further includes determining an average indoor temperature and an average external temperature for the predetermined time period based on the received plurality of indoor temperature measurements and received plurality of external temperature measurements, respectively, determining a rate of change of the plurality of indoor temperature measurements over the predetermined time period, and determining a performance factor of the structure, wherein the performance factor comprises the rate of change of the plurality of indoor temperature measurements divided by a difference of the average indoor temperature and the average external temperature.

In certain aspects, the performance factor is used to determine the energy efficiency of the structure and the temperature monitoring device is physically located in relative proximity to a thermostat associated with energy control of the structure. In another aspect, the temperature monitoring device is operatively connected to a thermostat associated with energy control of the structure. In one aspect, the rate of change of the plurality of indoor temperature measurements is determined by creating a first regression utilizing a starting temperature, an ending temperature, a plurality of temperatures between the starting temperature and the ending temperature, and the predetermined time period.

The method may further include creating a second regression utilizing a second starting temperature, a second ending temperature, and a plurality of temperatures between the second starting temperature and the second ending temperature, determining a second rate of change associated with a second predetermined time period, and identifying an intersection point of the first regression and the second regression.

In certain aspects, the intersection defines the transition between an on cycle and/or an off cycle of an HVAC system associated with the structure and the temperature monitoring device can measure temperatures at a 0.02° F. temperature difference.

According to one aspect, there is provided a system for analyzing energy efficiency of a structure, comprising a temperature monitoring device within the structure, wherein the temperature monitoring device is capable of sensing temperature measurements according to a predetermined time interval, and a processor in operative connection with the temperature monitoring device and operative to receive a plurality of indoor temperature measurements associated with the interior of the structure from the temperature monitoring device for a predetermined time period at the predetermined time interval, receive a plurality of external temperature measurements obtained from the exterior of the structure, and determine an average indoor temperature and an average external temperature for the predetermined time period.

The system further provides a processor operative to determine a rate of change of the plurality of indoor temperature measurements over the predetermined time period based on the received plurality of indoor temperature measurements and the received plurality of exterior temperature measurements, respectively, and determine a performance factor of the structure, wherein the performance factor comprises the rate of change of the plurality of indoor temperature measurements divided by a difference of the average indoor temperature and the average exterior temperature.

In certain aspects, the performance factor is used to determine the energy efficiency of the structure and the temperature monitoring device is operatively connected to a thermostat associated with energy control of the structure. Further, in one aspect, the temperature monitoring device can measure temperatures at a 0.02° F. temperature difference. According to one aspect, the rate of change of a plurality of indoor temperature measurements is determined by creating a first regression utilizing a starting temperature, an ending temperature, a plurality of temperatures between the starting temperature and the ending temperature, and the predetermined time period.

The system further provides a processor operative to creating a second regression utilizing a second starting temperature, a second ending temperature, and a plurality of temperatures in between the second starting temperature and the second ending temperature, determining a second rate of change associated with a second predetermined time period, and identifying an intersection point of the first regression and the second regression. In one aspect, the intersection point defines the transition between an on cycle and/or off cycle of an HVAC system associated with the structure.

According to one aspect, there is provided a method for analyzing energy usage in connection with a heating, ventilation, and air conditioning (HVAC) system associated with a structure, wherein by providing a temperature monitoring device is physically located within the structure, wherein the temperature monitoring device is capable of sensing temperature measurements according to a predetermined time interval, comprising receiving a plurality of inside temperature measurements associated with the interior of the structure from the temperature monitoring device for a predetermined time period at the predetermined time interval, receiving energy usage data for the structure over the predetermined time period, wherein the predetermined time period corresponds to an on or off cycle of the HVAC system, and determining a performance factor for the structure and correlating the building performance factor with the energy usage data for the structure for the predetermined time period to characterize the HVAC system operation.

In certain aspects, correlating the building performance factor with the energy usage data for the structure for the predetermined time period further comprises determining the energy usage per minute for the HVAC system, determining the total HVAC energy usage for the predetermined time period, and determining an impact of the HVAC energy usage on the total energy usage of the structure. In one aspect, the temperature monitoring device is operatively connected to a thermostat associated with energy control of the structure.

According to certain aspects, the method further comprises creating a second regression utilizing a second starting temperature, a second ending temperature, and a plurality of temperatures between the second starting temperature and the second ending temperature, determining a second rate of change associated with a second predetermined time period, and identifying an intersection point of the first regression and the second regression. In one aspect, the intersection point defines the transition between an on cycle and/or off cycle of an HVAC cycle associated with the structure.

In one aspect, the rate of change of a plurality of indoor temperature measurements is determined by creating a first regression utilizing a starting temperature, an ending temperature, a plurality of temperatures between the starting temperature and the ending temperature, and the predetermined time period. In one aspect, the temperature monitoring device can measure temperatures at a 0.02° F. temperature difference.

These and other aspects, features, and benefits of the claimed invention(s) will become apparent from the following detailed written description of the preferred embodiments and aspects taken in conjunction with the following drawings, although variations and modifications thereto may be effected without departing from the spirit and scope of the novel concepts of the disclosure.

### BRIEF DESCRIPTION OF THE DRAWINGS

The accompanying drawings illustrate one or more embodiments and/or aspects of the disclosure and, together with the written description, serve to explain the principles of the disclosure. Wherever possible, the same reference numbers are used throughout the drawings to refer to the same or like elements of an embodiment, and wherein:

FIG. 1 is an exemplary graph illustrating a typical summertime hour-by-hour energy profile of hourly interval meter data for one day, according to one embodiment of the present disclosure.

FIG. 2 illustrates an exemplary 5-minute data sample of energy use, according to one embodiment of the present disclosure.

FIG. 3 is an exemplary graph that shows a detailed 1-minute data capture for a 24-hour period of a home, according to one embodiment of present disclosure

FIG. 4 is an exemplary graph illustrating 5 minute kW data, according to one embodiment of the present disclosure.

FIG. 5 is an exemplary graph illustrating 15 minute kW data, according to one embodiment of the present disclosure.

FIG. 6 is an exemplary graph illustrating one hour kW data, according to one embodiment of the present disclosure.

FIG. 7 illustrates an exemplary approach to monitoring an existing thermostat device and capturing building thermal performance through the analysis and communication of this captured data, according to one embodiment of the present disclosure.

FIG. 8 is an exemplary graph illustrating a heating cycle as defined by a plurality of temperatures and associated times, according to one embodiment of the present disclosure.

FIG. 9 are exemplary block diagrams illustrating a comparison between mild and cold weather heating, according to one embodiment of the present disclosure.

FIG. 10 are exemplary block diagrams illustrating a comparison between mild and cold weather heating, according to one embodiment of the present disclosure.

FIG. 11 is an exemplary graph illustrating the sensing and inference procedure, according to one embodiment of the present disclosure.

FIG. 12 illustrates exemplary data regression of on and off cycle inferencing, according to one embodiment of the present disclosure.

FIG. 13 is an exemplary chart illustrating the raw minute-by-minute data for a typical day when the heating system is operating, according to one embodiment of the present disclosure.

FIG. 14 is an exemplary graph that illustrates a tablature of all the available data into an hourly summary of how many minutes a heating system was on, according to one embodiment of the present disclosure.

FIG. 15 is an exemplary graph illustrating an assumption that thermal gains existing in the home (appliance activity, people and pets in the home all day, lights, electronics, etc.) are all consistent during the data analysis period.

FIG. 16 is an exemplary graph illustrating a characterization of internal gain in a home, wherein an internal gain generally comprises heating of a structure due to internal activities or internal heat sources, according to embodiment of the present disclosure.

FIG. 17 is an exemplary graph illustrating a bedroom thermostat with the simultaneous recordings from the adjacent bathroom on just one evening.

FIG. 18 illustrates one embodiment of the manner in which the proposed device and analysis methods are implemented.

FIG. 19 illustrates one embodiment of the manner in which the proposed device and analysis methods are implemented.

FIG. 20 is an exemplary schematic of a thermostat/temperature monitoring device, according to one embodiment of the present disclosure

FIG. 21 is an exemplary block diagram describing the process of capturing and analyzing temperature and thermostat data utilizing a TMD, according to one aspect of the present disclosure.

### DETAILED DESCRIPTION

### Overview

For the purpose of promoting an understanding of the principles of the present disclosure, reference will now be made to the embodiments illustrated in the drawings and specific language will be used to describe the same. It will, nevertheless, be understood that no limitation of the scope of the disclosure is thereby intended; any alterations and further modifications of the described or illustrated embodiments, and any further applications of the principles of the disclosure as illustrated therein are contemplated as would normally occur to one skilled in the art to which the disclosure relates. All limitations of scope should be determined in accordance with and as expressed in the claims.

Aspects of the present disclosure generally relate to devices and methods for capturing the time and temperature at which a thermostat(s) in a structure (i.e., residential home, multi-family home, commercial building, etc.) turns on and turns off, and then analyzing those times and temperatures at particular granularities to identify improvements in energy usage. These time and temperature data points are some of the useful information needed to determine two performance attributes in the structure: the ramping time when the HVAC system is returning the home to the comfort setting (which is called herein the “system on time”), and the ramping time for the home to hit the next on cycle or the “system of time”.

In one aspect, by monitoring the time and temperature data and comparing that to outside air temperatures, many attributes of the home and its HVAC system can be determined. According to one aspect, degradation over time of the HVAC system will show in trends in the on time vs. outside air temperature. Improvements in the HVAC system will lower the energy inputs to the home but the system on time may not go down and in fact might go up given the new system was sized smaller to reflect the improved insulation and air infiltration in the home. The examples (as described in greater detail below) are numerous.

In one aspect, the analysis of system off time and how the home returns to the controlled on time during these off times characterizes the shell and the internal gains in the home. In one aspect, monitoring and reporting these off times to a homeowner along with the amount of time the system(s) is on transforms thermostat understanding. For example, learning that one-degree change can reduce operating hours on the HVAC system can influence consumer behavior. Further, learning that setting the thermostat to 78° F. lowers the energy called for in the cooling system by 20-30% compared to 75° F. can be made real to customers by showing them that in their existing thermostat.

According to one embodiment, the device and methods described herein do not require the homeowner to change his/her thermostat. Instead, the device simply monitors the existing thermostat, provides intuitive information to a homeowner on his/her mobile phone and/or on a website correlating to his/her personal energy use, and helps him/her understand what he/she can do about it. In other embodiments, the present thermostat/temperature monitoring device (TMD) can replace an existing thermostat and provides the relevant information obtained via the TMD. In one embodiment, the method does not require the homeowner to attach the terminals in the TMD to the existing thermostat to produce the claimed benefits.

### Discussion of Industry Practice

Aspects of the present disclosure generally relate to devices and methods for implementing thermostat-monitoring devices (TMDs) (also referred to herein as temperature-monitoring devices) in operative communication with any existing thermostat device and monitoring the existing thermostat device and capturing home energy performance through the analysis and communication of this captured data. Based on the embodiments described herein, information may be obtained from existing HVAC systems and thermostats within a home or residential building in a manner and with a granularity that have been previously impossible. The present devices and methods will be described in greater detail in the attached exhibits, documents, and illustrations.

The traditional perspective of collecting energy data in the energy industry is meter centered. The energy utility industry tends to talk about kW, kWh, or BTUs per month when describing energy use. While the recent America Recovery and Reinvestment Act of 2009 (ARRA) funding for smart grid raised the specter of many Americans getting better than monthly information, this has not proven to be any more informative, engaging or motivational.

Professionals have long tried to use Cooling Degree Days (CDD) and Heating Degree Days (HDD) to create an intuitive reference point for these decisions but they simply do not work for the average person. The energy utilities in the US and around the world have tried for decades to get customers to understand this by putting HDD, CDD and the average temperature on the bill. They have tried graphing it to drive the point that they go up and down and the bills tend to track the same pattern. The methods just do not work effectively with respect to customer engagement.

The latest hope in the electric utility industry was that the smart grid and smart meters (also known as communicating electric meters with 15 minute or hourly intervals) would give customers the information that would engage them by showing energy use closer to real time. While there is a significant press about the smart grid, especially in Europe where the decision was made to implement it countrywide in many cases, most US electric utilities do not have hourly meters for residential energy use today. Those that do have interval meters are really struggling with the user experience. While there are occasional homeowners who install in-home devices (IHDs) that can indicate electricity consumption in 1-5 minute intervals, these IHDs have many drawbacks. Primarily, the IHDs remain meter-focused, and thus do not provide relevant and granular information needed for a true energy usage analysis. In addition, the vast majority of American residential customers do not have smart grid data available to them.

Critics of electric utilities thought the problem must be that the traditional electric utility ideas were inadequate, so the key to success would be to let the free market determine with value propositions that engage customer interest. However, the free market cannot access the smart grid data because it is controlled by the utilities. Addressing that problem, the US government has attempted to make this data available in standardized formats so that customers could have their smart grid data made meaningful by others.

The US energy utilities have a long history of promoting energy efficiency. The results of these programs have been impressive, especially in California where energy-use per household has remained essentially flat in comparison to any other area in the US. However, the attempts to engage residential customers using meter-data to support their energy improvements have largely been ignored.

Therefore, a traditional Meter Centered Paradigm (MCP) is one point of view for billing customers for their energy use, but it poses challenges when one tries to communicate homeowner behavioral and energy efficiency improvement ideas, especially when one looks at the crude granularity of the traditional meter-data the industry considers relevant to the business at this time. Further, it fails to identify and quantify home improvements and behavioral changes a customer makes due to the broad granularity of the data captured.

Further disadvantages associated with smart grid data is the inability to engage the average consumer; is the smart grid providers cannot get the customer to look at it more than once. Yes, they can push it to them in weekly summary emails and customers will open the email, but often customers still do not know what they are looking at. And even though experienced professionals might find 1 to 5 minute data interesting to look at, it becomes impossibly complex to understand at those times when the house uses most of the energy, in the evening . . . precisely the time of the day when really important energy-use decisions are going on in the home that a homeowner should know about. According to one aspect, one of the reasons electric utilities have stressed the benefits of smart meters is to be able to offer customers time-dependent price signals to reflect the fact that electric utility costs (or opportunities to save money) are time dependent. The very hot summer afternoons often have high prices in the regional electricity markets. It would be appropriate to signal customers to that fact and share the benefits of reducing electrical loads during these periods. The same situation occurs on the coldest days in the winter for some electric utilities in the southern parts of the US.

In certain embodiments, the mechanisms described herein offer a low-cost and verifiable way for these same electric utilities to promote time of use rates to customers who do not have a smart meter. Further, the mechanisms described herein document the activities of the HVAC systems in the home. In addition, the energy use is proportional to these measurements. As a result, an electric utility could offer a peak time rebate for changes in the air conditioner setting and know for sure what the customer did in response.

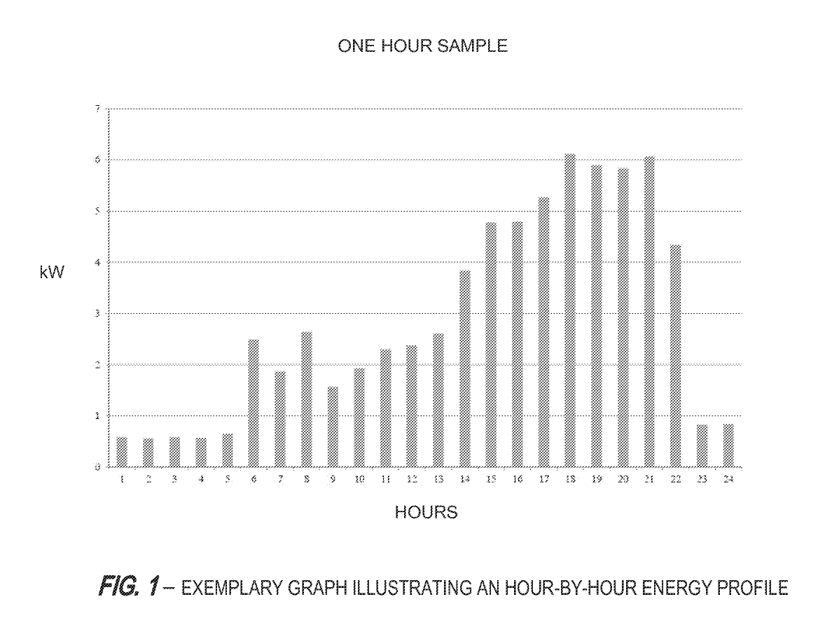

FIG. 1 is an exemplary graph illustrating a typical summertime hour-by-hour energy profile of hourly interval meter data for a structure (e.g., a home or building) for one day (since that is the minimum resolution most US utilities provide to customers). In one embodiment, the data within FIG. 1 illustrates how end-use load disaggregation is done (to identify the HVAC system, refrigerators, etc.) and how these end uses can be identified (the signal for the end-use items desired) from the noise (everything else going on in the house) in the electric profile.

The vertical scale is kW in each hour (the kWh per hour). The horizontal scale is the hour of the day. The low energy use overnight is observable, as shown during the hours of 0-6 and 23-24 and this is typically the combination of refrigerator operation, lights and electronics being left on plus the phantom loads (energy used by appliances even though they are turned off). As shown in FIG. 1, this house “wakes up” at around 6 in the morning, but it is hard to distinguish specific activities as it could be from cooking, lights, blow dryers, TVs, etc.

Over time, the day-by-day variations in this profile will trend with the weather so that the kWh in each day associated with the AC (or heating during the winter) can be determined using simple linear regression, but it is impossible to know with any level of certainty how much AC is occurring on any given day, no less in any given hour. That certainty changes as the intervals are shortened from one hour, to 15 minutes and down to 5 minutes or 1 minute, as we will be described.

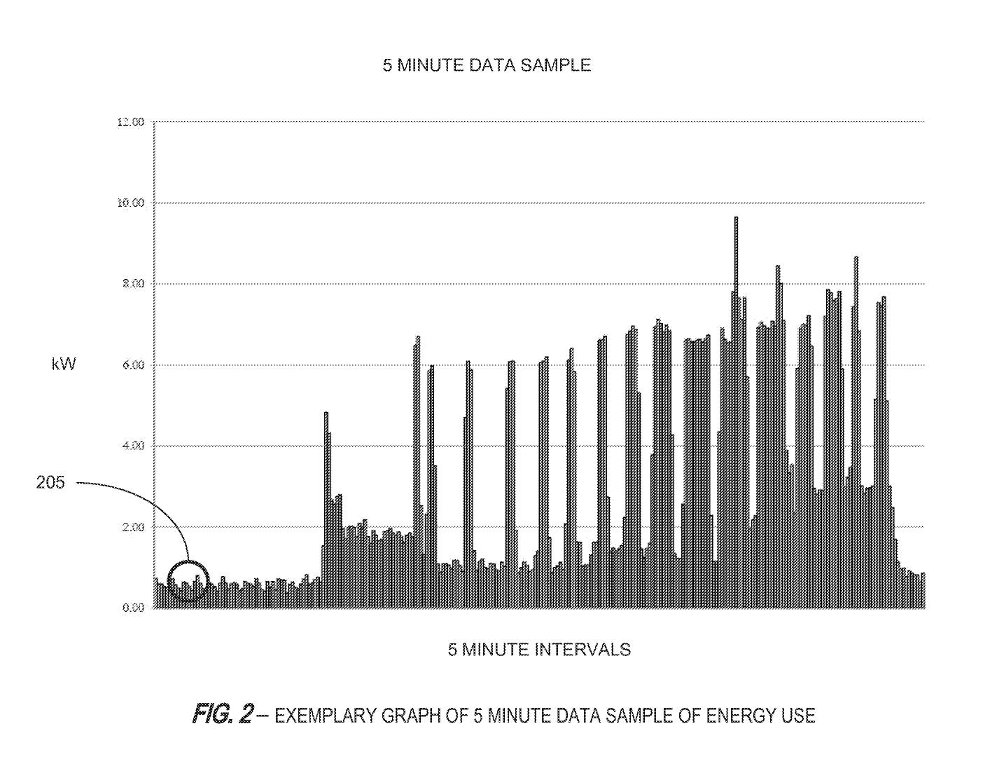

FIG. 2 illustrates an exemplary 5-minute data sample of energy use for the same structure of FIG. 1 on the same day, but with 5-minute data. It is shown that the refrigerator is cycling at night 205, but it is not definitive. There are times when 5-minute data can show this clearly and times when it does not. Isolating refrigerator cycling depends heavily on two things: how quiet the house is electrically at night (i.e., is anyone awake and doing things) and how old the refrigerator is. Generally, older units cycle more frequently, while a new one might only cycle on/off about once an hour.

A 5-minute data sample also illustrates the AC cycling on and off during the day and the AC running more and more in any one hour as the day wears on. You can also see the other loads (probably a combination of lights, TVs, computers, game consoles, etc.) building in the morning and in the evening. Some of that might be cooking as well, but again this analysis is not definitive.

The structure in connection with this exemplary discussion has a lot of noise starting around 6:00 a.m., running through midnight. If it were a “quiet day” at the same time of the year when the AC was running but nothing else was happening during the day, the “difference” could be taken between these two profiles and one might infer the non-HVAC and Refrigeration loads rather nicely, but one still would not be able to detect the difference between the lights, TVs, etc.

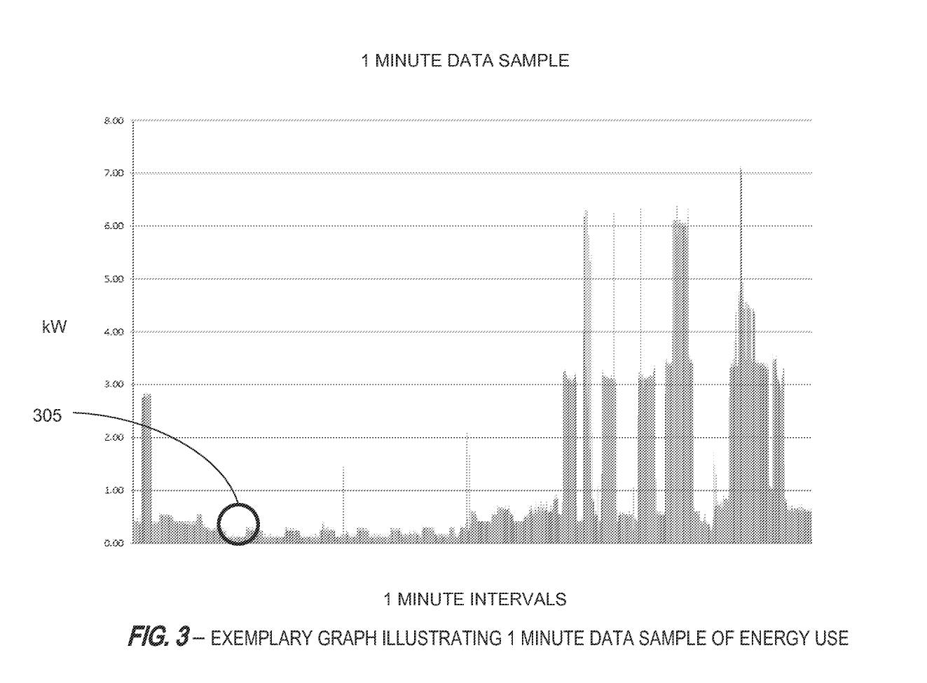

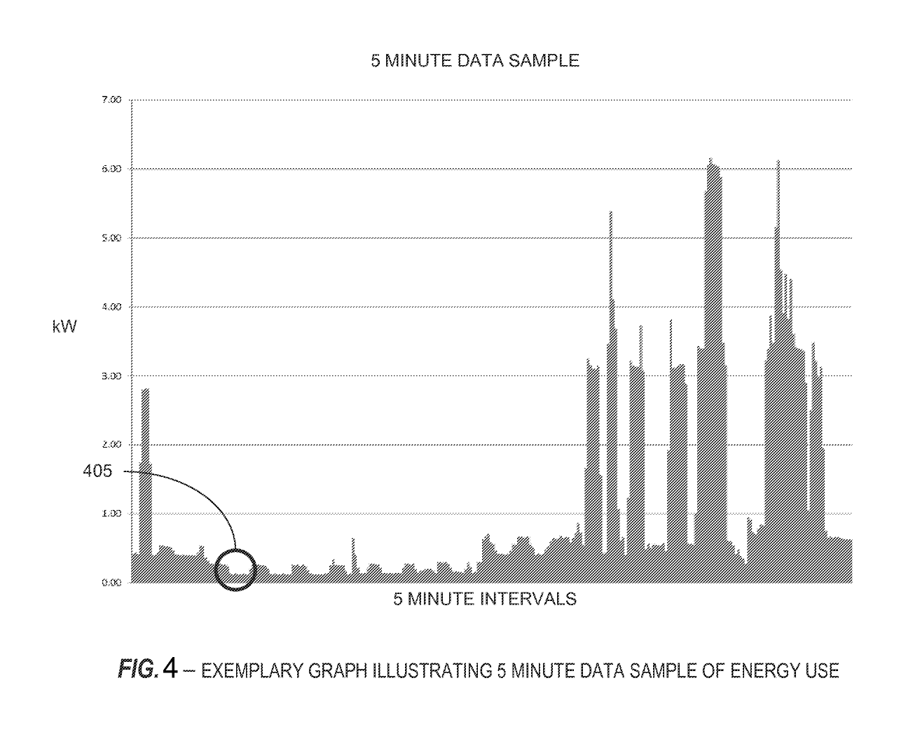

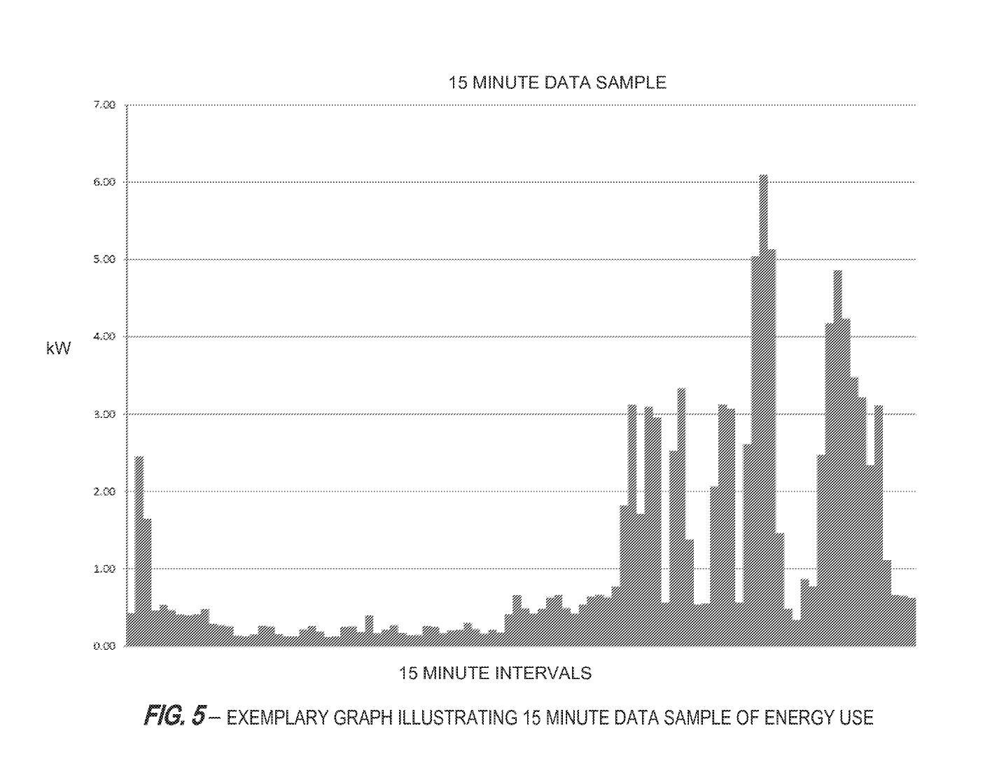

FIG. 3 is an exemplary graph that shows a detailed 1-minute data capture for a 24-hour period of a home, according to one embodiment of present disclosure. The subsequent graphs shown in FIGS. 4, 5, & 6 were derived by averaging this same 1-minute data in larger and larger intervals. First, the data is in minute intervals (the best smart grid data available in the US at this time) and finally shown in hourly intervals (the most common smart grid interval data available).

It is easy to see the refrigerator cycling on and off in the 1 minute data 305 and it is still clear in the 5-minute data 405, as shown in FIG. 4. The 1-minute data also indicates some very short acting electric loads (often a microwave oven) but one cannot be certain about the exact source.

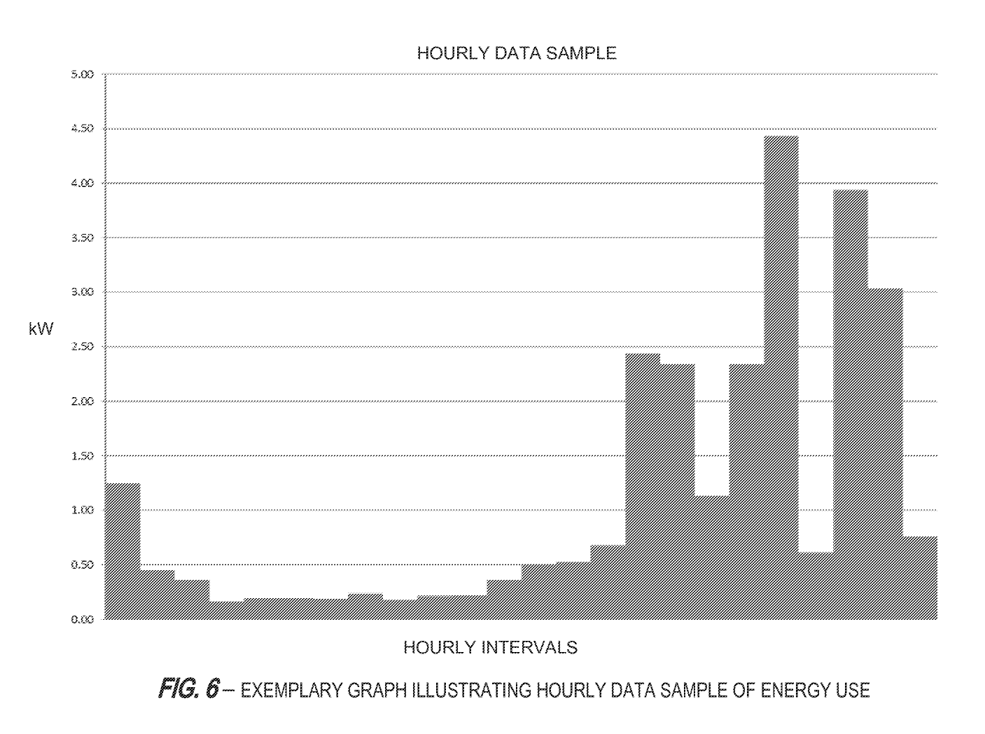

FIG. 5 is an exemplary graph illustrating the similar energy usage data as FIGS. 3 & 4, but the data is sampled at 15-minute increments. As shown, 15-minute data captures “most of the detail” that the 5-minute data shows (FIG. 4) and even does a reasonable job compared to the 1-minute sample data captures (FIG. 3). However, hourly data, as shown in FIG. 6 masks almost all the details. One can still detect the kWh per day in the heating and cooling loads over time, but one would not know the story in any one day with confidence.

Accordingly, it is possible to “estimate” the average kWh a day over time, so weekly total kWh for cooling and heating are easily computed using even hourly data. The question is whether it is possible to accurately/confidently disaggregate any one-day's kWh into almost anything using hourly kWh and the answer to that is almost certainly a no.

Therefore, given that 1-5 minute data fails to deliver the information needed, and the electric utility industry has no business reason to embrace interval metering in less than hourly intervals, the industry is at an impasse with the MCP

### Exemplary Embodiment

As previously discussed, an HVAC system is one of the largest energy consuming appliances within a building. Accordingly, due to climate control and user comfort, in some regions an HVAC system routinely operates to maintain a desired temperature or comfort level within a building/dwelling. Further and as previously discussed, it is difficult, using traditional data captured from a power meter, to isolate, track, and analyze a building's energy use due the operation of the HVAC system.

In one embodiment, a Thermostat Centered Paradigm (TCP) (as described herein) works well for analysis of HVAC and water heater energy use and overcomes the presentation and intuition problems associated with the MCP. In addition, given that the three largest energy users in a home are heating, cooling and water heating, the TCP is advantageous since almost everyone has these thermostats in place. Further, and in one aspect, the TCP can be utilized to determine a building thermal performance factor, wherein the building performance factor defines a building's or structures (e.g., residential, commercial, single-family, etc.) ability to maintain a comfortable climate. In other words, the building performance factor describes a building's ability to hold in heat and maintain a warm (comfortably) building in the wintertime. Alternatively, the building performance factor can also describe a building's ability to retain cooler air within the home during the hotter summer months.

In one embodiment, the TCP utilizes temperatures within the building and times associated with the temperatures to identify the various climate cycles within the building. As described herein, a climate cycle generally comprises a heating and/or a cooling cycle, wherein the cycle is determined by the time period required for the HVAC system within a building to reach the desired comfort temperature (the temperature at which the thermostat is set and at which the building tries to maintain) and how long it takes for the home to lose that comfort temperature. The present methods described herein utilize a thermostat/temperature monitoring device (TMD) that can monitor and record temperatures within the home and a timestamp that is correlated to each recorded temperature. The aforementioned device and methods associated with said device will be discussed in greater detail below.

One embodiment of the proposed method applies as a retrofit to all existing thermostats. Accordingly, a homeowner does not necessarily need to install a new thermostat. In one embodiment, a TMD is placed in relative proximity (e.g., on and/or near the wall) to the existing thermostat. In one embodiment, the present disclosure focuses on the analysis of two cycles in all thermostats that has historically been ignored: the on and off cycles of temperature and time, wherein the on cycle is the time the HVAC is running and the off cycle is the time the HVAC is off. Further, modern thermostats do not provide any information about what the house is doing as soon as the HVAC system turns off.

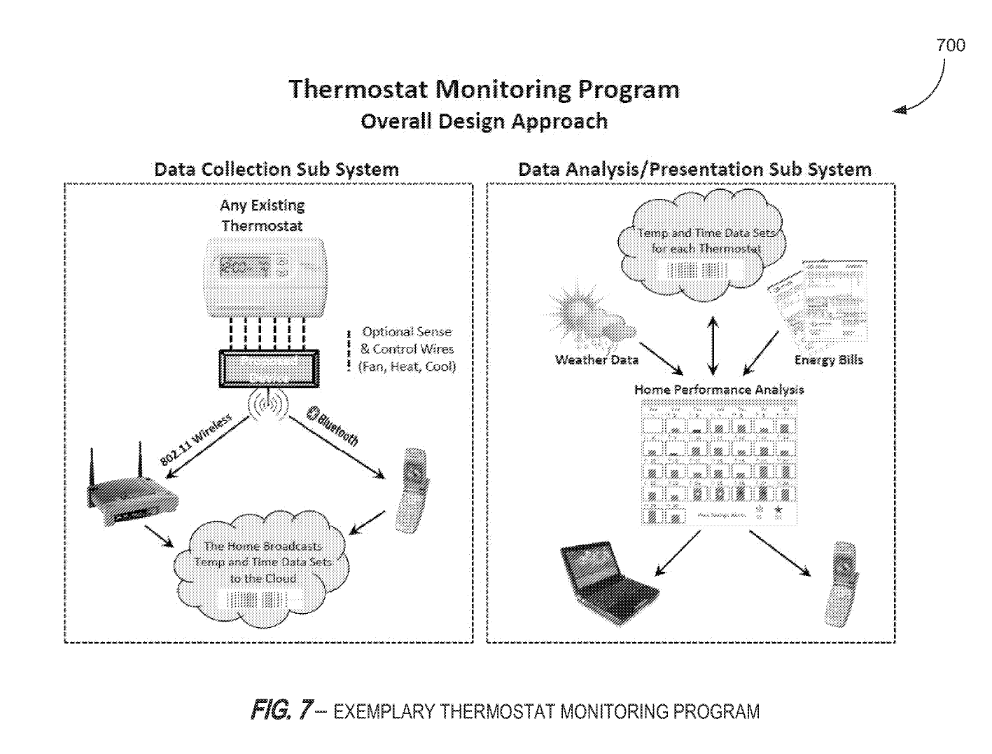

FIG. 7 is an exemplary block diagram 700 illustrating an approach to monitoring an existing thermostat device and determining building thermal performance through the analysis and communication of this captured thermostat data, according to one embodiment of the present disclosure. In certain embodiments, the TMD can simply be placed near the existing thermostat to record the temperature and the time when the thermostat turns on and turns off the HVAC system. The concept goes beyond just a data logging concept and captures by either data manipulation or outright wired sensing the on and off cycle points on the thermostat over time. In one aspect, the on and off cycle points can be used to derive energy use attributes for the home and the HVAC system. The present disclosure details analytics, which describe the energy efficiency and thermal behavior due to energy used, and will enable the presentation of intuitive aggregate home energy performance attributes, shown in FIG. 7 as a periodic (e.g., monthly) bar chart of energy use by the heating and cooling bars to indicate energy use by the HVAC system.

In one embodiment, thermostatic devices typically are not proportional acting devices as in they are typically either on or they are off. In addition, the devices they control are typically not proportional either. Generally, the devices run at full capacity until they are turned off. While there are variable speed heat pumps and air conditioners in the market today, they are not the primary devices in the marketplace. Over 99% of the existing HVAC devices are simply on or off.

Therefore, the heating and cooling systems may use essentially the same amount of energy whenever they are on. The total energy use is simply the time they operate multiplied by the amount of energy they use when they operate (Energy=Power×time). Said another way, given a heating system that uses about 3 kWh of electricity for every hour it operates, energy use can be approximated well by just noting the hours the system operates in the home.

It is instructive to report total run-time in each day, but it is often far more educational and operationally valuable to know the system run-time in each hour because another intuitive attribute is gained when this is done. If an air conditioner ran all the time during an hour, it can also be inferred that it is running at full capacity. If the air conditioner ran 30 minutes out of the hour, it is running at half capacity. Therefore, defining the operating minutes in an hour produces an intuitive and highly instructive attribute for customer engagement. For example, consider what might happen on an extremely hot summer afternoon. The air conditioner might never turn off and in actuality, the indoor air temperature might be rising above the set point. This is extremely helpful information. However, there is even more to be gained through analysis of the off cycles.

In one aspect, many thermostatic devices “turn the device on” at one temperature set point and run until they satisfy the set point that turns them off. As will be generally understood, ‘T’ is defined for temperatures and “t” for time herewith, the most common convention used in engineering mathematics. Therefore the data sequence is T (t), which in plain English means that Temperature (the symbol T) is a function of time (the symbol t). Since the set points in the control system are fixed by the thermostat design itself, the thermostat setting will be defined as the average temperature (the comfort setting the customer wants). The thermostat will have a low set point at T minus about 0.2 to 0.5° F. and a high set point at T plus about 0.2 to 0.5° F. That is, the bistable set point is about 0.4 to 1.0° F. wide. Very old thermostats have been known to have 2-3° F. bistable set points.

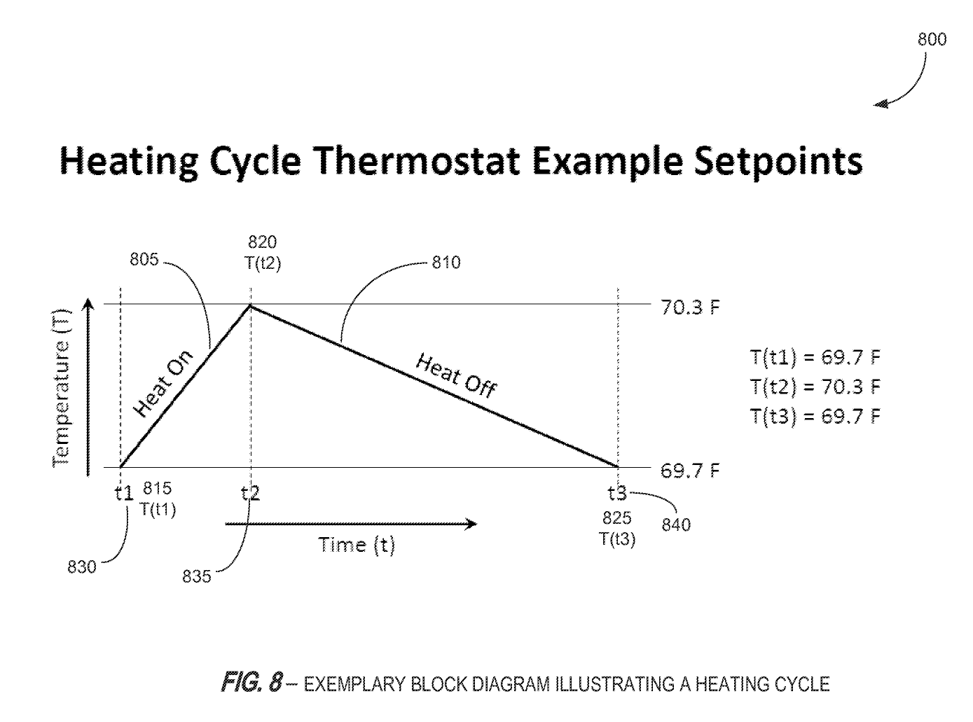

FIG. 8 is an exemplary graph 800 illustrating a heating cycle as defined by a plurality of temperatures and associated times, according to one embodiment of the present disclosure. In one aspect, the temperature and time correlation can help determine when a thermostat turned on and when a thermostat turned off in a given structure. As an example and illustrated in FIG. 8, assume a homeowner set the thermostat to 70° F. for a heating system. The thermostat would probably turn the heat on at 69.5-69.8° F. range depending upon the age and design of the thermostat and it would run continuously until it satisfied a temperature between 70.2-70.5° F. If the outside air temperature was constant and well within the heating capability of the system, and there were no changes in homeowner behavior, you can imagine a saw-tooth graph with repeating patterns. The heating system drives the temperature up from the onset point until it satisfies the demand at which time it turns off and the natural heat losses of the house drive the falling temperature part of the pattern. The saw-tooth will have a height that averages out to be the width of the bistable set points and normally somewhat close to the comfort setting. The one shown here is for a 70° F. set point and typical bistable behavior.

The analysis mechanisms described in the present disclosure relate to the timing marks t1, t2, and t3. As shown in FIG. 8, the actual saw tooth pattern for each HVAC system in a home is much like an EKG. According to one aspect, it contains a wealth of “home health” information that can be extracted and reported to homeowners, trade allies, and the energy companies serving this home to help them.

In one aspect, some of the parameters described herein to determine a building's thermal and energy analytics are the temperatures at which the HVAC turns on and off, and the timing marks of the saw-tooth cycle t1, t2, and t3. The precise temperature itself might be in some doubt, but the bias from the true known temperature remains essentially constant at each temperature. For example, if the TMD was reading and recording temperatures that were 1° F. high or low, the TMD will continue to read and record temperatures that are high or low by the same amount over time. Therefore, the actual accuracy of the temperature does not matter that much. It is far more important to note the timing marks for how the thermostat is cycling and the differences in temperature between those timing marks.

In one embodiment and as previously discussed, a building thermal performance factor can be determined utilizing, among other things, recorded indoor temperatures and the timestamps associated with the recorded temperatures. As shown in FIG. 8 and in one aspect, the heat on cycle 805 is displayed as a positive slope and describes the starting temperature with which the thermostat engaged and started the HVAC system to heat the building T(t1) 815 and the ending temperature with which the thermostat ceased HVAC operation T(t2) 820. In another aspect, the heat on cycle also describes the time with which the HVAC system started t1 830 and the time with which the HVAC system ceased operation t2 835.

In one embodiment, the building performance factor (BPF) is defined according to the following equation:

$$BPF = \frac{Δ T}{IAT - OAT}$$

wherein ΔT=the on or off cycle slope, IAT=the average inside ambient temperature during the associated on or off cycle, and OAT=the average outside ambient temperature during the associated on or off cycle. As is generally understood, the on or off cycle slope is generally defined as

$$\frac{d T}{d t}$$

for the on or off cycle.

Referring back to the exemplary discussion in connection with FIG. 8, for exemplary purposes IAT1 will equal the indoor ambient temperature at t1, IAT2 will equal the indoor ambient temperature at t2, OAT1 will equal the outdoor ambient temperature at t1, and OAT2 will equal the outdoor ambient temperature at t2. As will be generally understood, since IAT1 and IAT2 are indoor ambient temperatures and T(t1) and T(t2) are the indoor temperatures at which the thermostat engage and disengage the HVAC, it will be understood that IAT1=T(t1) and IAT2=T(t2). For this exemplary discussion t1=9:06, t2=9:15, OAT1=60.1 F, and OAT2=60.2 F. Further, as illustrated in FIG. 8, T(t1)=69.7 F and T(t2)=70.3 F, which as previously identified also equal IAT1 and IAT2 respectively.

According to one embodiment, the time it takes for a building to reach its desired temperature depends on various aspects, such as the type of insulation used in the structure, whether or not high efficiency windows are installed, the position of the house relative to the sun, etc., but overall the level of the building's thermal performance dictates the speed with which the building reaches the desired temperature as well as how long the building maintains the desired temperature. Accordingly and in one aspect, a building with a better building thermal performance would heat and/or cool faster than a building with a worse building thermal performance. Further, generally, a good BPF is between approximately 0-5%, a medium BPF is around 10-14%, and a poor BPF is greater than 15%.

According to one aspect in connection with the FIG. 8 exemplary discussion and solving for ΔT:

$$Δ T = \frac{d T}{d t} = \frac{T ( t 2 ) - T ( t 1 )}{t 2 - t 1} = \frac{70.3 - 69.7}{9 \text{:} 15 - 9 \text{:} 06} = \frac{.6}{9} = .06 F \text{/} min$$

In one aspect, ΔT is scaled to an hourly factor by multiplying by ΔT by 60.

0.06 F/min×60=3.6 F/hr

In one aspect, IAT equals the average indoor temperature between 9:06 and 9:15 and OAT equals the average outdoor temperature between 9:06 and 9:15. Accordingly,

$$IAT = \frac{69.7 + 70.3}{2} = 70$$

such that IAT=70 F. Likewise, for the exemplary discussion OAT=30° F.
Last and in another aspect to solve for the building performance factor (BPF):

$$BPF = \frac{Δ T}{IAT - OAT} = \frac{3.6}{70 - 30} = 0.9 or 9 \%$$

As, previously discussed, 9% for this exemplary building's building performance factor is roughly a medium building performance. According to one aspect, this indicates that this particular building generally takes relatively longer to heat and to cool than buildings with a good BPF. In another aspect, it also indicates that the building generally loses inside temperatures quickly. In one embodiment, slope is calculated via a linear regression of many points, such as using a starting temperature, an ending temperature, and the points that are in between the starting and ending temperature. In one aspect, the present system uses standard linear regression techniques as will be generally understood by one of ordinary skill in the art.

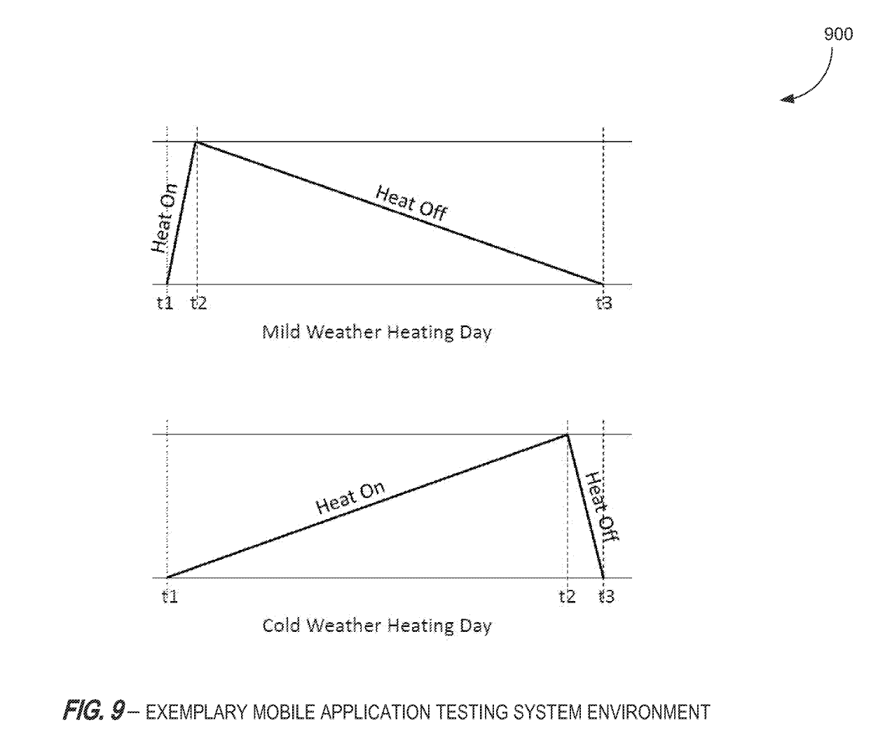

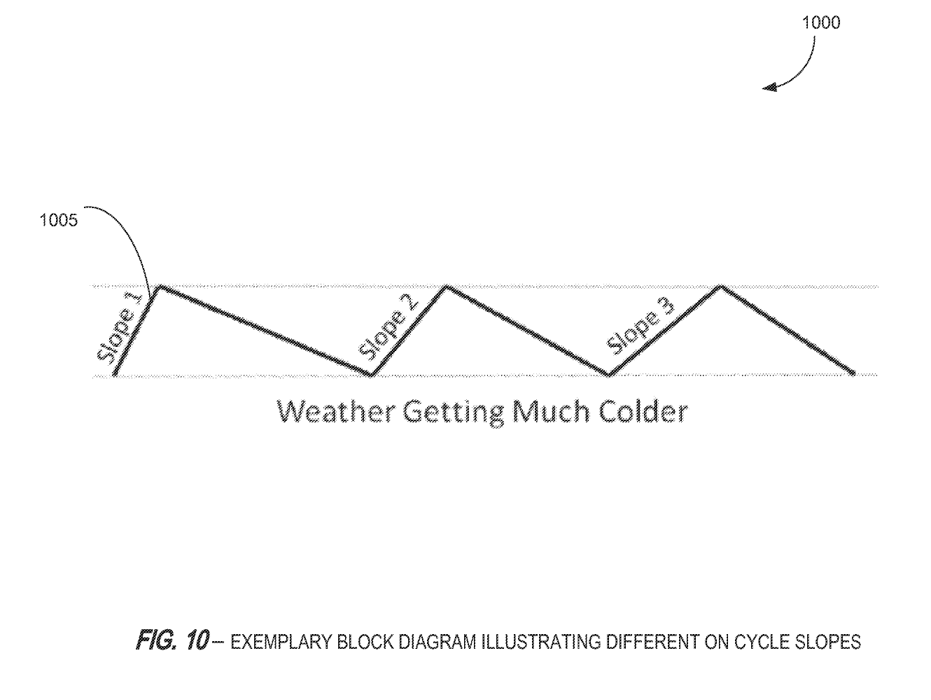

FIGS. 9 and 10 are exemplary graphs 900 and 1000 illustrating a comparison between mild and cold weather heating, according to one embodiment of the present disclosure. As will be generally understood, in one aspect, on a colder day, it will take a longer system on cycle to heat the inside of a building to the desired temperature. Alternatively, in one aspect, on a milder or warmer day, it will take a relatively shorter system on cycle to heat the inside of the building to the desired temperature. In one aspect, and as shown in FIG. 9, the shape of the saw-tooth changes as the weather becomes more severe. In one aspect, the graphs shown here are for the heating cycle. In another aspect, graphs for the cooling cycle are simply inverted patterns of these. The temperature drops when the cooling comes on. Here, the temperature rises as the heat comes on.

In one aspect, the saw tooth graph shape changes for a mild day (when the temperature outside might be 50° F.) compared to a very cold day when the outside air temperature is 20° F. The heater is running more often on the colder day and it is also shown by the rate at which the temperature falls when the heater turns off. Further, the slope of the “on cycle” depicts a longer run time because the heater is much less effective at raising the temperature. In one embodiment, characterizing the rise and fall saw-tooth patterns can identify and quantify changes to a house (improvements to the insulation, infiltration, and to the HVAC units themselves) as well as how energy use changes with home behavior (thermostat settings, activities in the home, leaving lights on, etc.). According to one aspect, as the outside temperature fluctuates, the BPF remains constant, such that the time associated with changing the temperature within the house shortens or lessens in a manner that maintains relatively the same BPF. Further, the length of time the house loses interior temperatures also fluctuates such that the BPF remains relatively constant.

It is instructive to convert the electric utility industry's typical meter centered paradigm (MCP) for heat pump operation into the thermostat centered paradigm (TCP) point of view. Assume, a customer has an electric heat pump unit that uses about 4,000 watts (4 kWh/hr.) whenever it is running, which is typical for a late model heat pump.

Table 1 is an exemplary spreadsheet summary of times the heat is turned on by the thermostat. Each row in this table is one 15-minute interval time meter recording period.

TABLE 1
Exemplary Thermostat On and Off Times
Example: Apogee Bil Analysis estimates
HVAC to be 4 kW for this customer

| Time | | | Minutes | | |
|---|---|---|---|---|---|
| 12 midnight | Tstat On t's | Tstat Off t's | On Time | kW Est | Tstat T |
| 12:00 PM | 12:10 PM | | 5.0 | 1.33 | 70 |
| 12:15 AM | | 12:17 PM | 2.0 | 0.53 | 71 |
| 12:30 AM | 12:32 PM | | 13.0 | 3.47 | 70 |
| 12:45 AM | | 12:46 PM | 1.0 | 0.27 | 71 |
| 1:00 AM | Set Tstat to 65 overnight | | 0.0 | 0.00 | |
| 1:15 AM | So there is a gap in | | 0.0 | 0.00 | |
| | operation | | | | |
| 1:30 AM | | | 0.0 | 0.00 | |
| 1:45 AM | 1:48 AM | | 12.0 | 3.20 | 65 |
| 2:00 AM | | 2:01 AM | 1.0 | 0.27 | 66 |
| 2:15 AM | | | 0.0 | 0.00 | |
| 2:30 AM | 2:40 AM | | 5.0 | 1.33 | 65 |
| 2:45 AM | | | 15.0 | 4.00 | |

In this example, the unit comes on 10 minutes after midnight and runs for 5 minutes during that interval. Because it ran until 12:17 p.m., it runs for 2 minutes in the next interval. It starts running again at 12:32 and runs until 12:46, so it runs for 13 minutes in the first interval and 1 minute in the next. The thermostat then goes to its nighttime setback of 65 degrees so it stays off until 1:48 a.m. when it runs to 2:01 a.m., comes back on once again at 2:40, and runs until 3:00 a.m. The table above summarizes the math and estimates the kW that would be measured in each of the 15-minute intervals that utilities would use to bring this to the customer's attention.

Table 2 is a table correlating the same data as illustrated in table 1, but as it is used in a typical MCP. Table 2 illustrates what a customer would see for each of the 15-minute periods early in that morning period. In one aspect, this generally communicates little relevant information to a customer. However, if the timestamps were recorded when the HVAC unit did run along with the temperature of the space at those on and off timing marks, a powerful and meaningful visualization is created as shown in table 2 wherein the electric load is to the left and thermostat temperature on the right.

TABLE 2
MCP Data of Exemplary Thermostat On and Off Correlating to Table 1

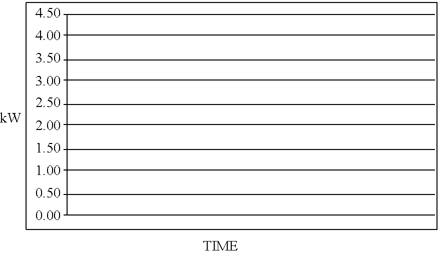

In on embodiment, time stamping the thermostat and using this information to help understand how a thermostat is really operating and when a structure is really using energy this way is helpful and unconventional. In addition, the mathematical procedures described herein, while simple, yield an enormous insight into the way a structure is actually reacting to weather and thermostat settings.

FIG. 10 is a graph 1000 illustrating different cycle on slopes in connection with a typical winter night, wherein the saw tooth illustrates the temperature changing (getting colder) through the night, according to one embodiment of the present disclosure. The raw data is an informative set of temperatures and timing marks that describes how the home is behaving. For example, on a typical winter night where the temperature drops rapidly, FIG. 10 illustrates how the saw-tooth characteristic of the heating cycle changes over the night.

In one embodiment, slope 1 (1005) will get smaller (slope 2) and smaller (slope 3) because the heating system is working longer and longer to satisfy the thermostat setting as the outside air temperature drops. In addition, the time until the next heating cycle is shortening and the slope of the temperature drop when the heat goes off is steepening for the same reason. These slopes also depend upon the thermostat setting itself (which we of course know in this paradigm) since a home that is set at 72° F. in the heating mode will cool off much faster than one being held at 70 F. It will also be harder for the heater to heat the home at 72° F. than at 70° F. Therefore, the house energy behaviors can be characterized by the time it takes for the heating system to achieve the on cycle and the time it takes for the home to bring about the next cycle.

In one embodiment, measuring the time transitions accurately can be achieved by directly sensing the closure of the contacts in the heating equipment (e.g., via an operative connection of a TMD to a thermostat) or can be inferred by calculating the transition time from off to on mathematically from logged temperature vs. time at periodic (e.g., one-minute, etc.) intervals. In one embodiment, the time interval can be determined by measuring the on and off time of the existing thermostat as it closes and opens the switch. In one embodiment, the wires from the thermostat switch contacts are connected to the input sensing contacts in the device shown and described later in the present disclosure. In one embodiment, a monitoring device may be placed near the existing thermostat to provide an accurate and helpful level of information.

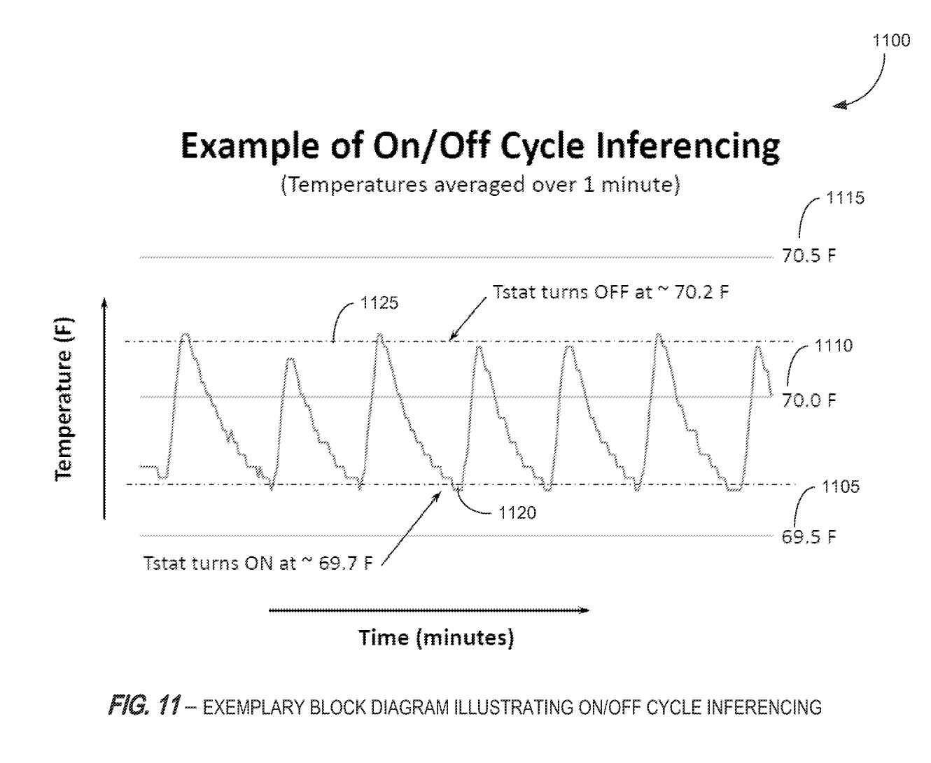

FIG. 11 is an exemplary graph 1100 illustrating a sensing and inference procedure, according to one embodiment of the present disclosure. The data shown here was collected at 1-minute time intervals and illustrates how the temperature notches up and down in a jagged line rather than as a smooth curve. In one embodiment, a temperature sensor 2010 (as described in greater detail below) has a precision of about 0.04 degrees ° F. In one embodiment, the latest temperature sensor 2010 in the described TMD has a resolution much better than of 0.01 degree F.

According to one aspect, the horizontal lines drawn at 69.5° F. 1105, 70.0° F. 1110 and 70.5° F. 1115 indicate that the thermostat was set at around 70° F. (and that is what would normally be shown to the homeowner), but it is turning on at around 69.7° F. 1120 and turning off at about 70.2° F. 1125. In one aspect, linear regression can be used to determine the precise time and temperature when a transition occurs.

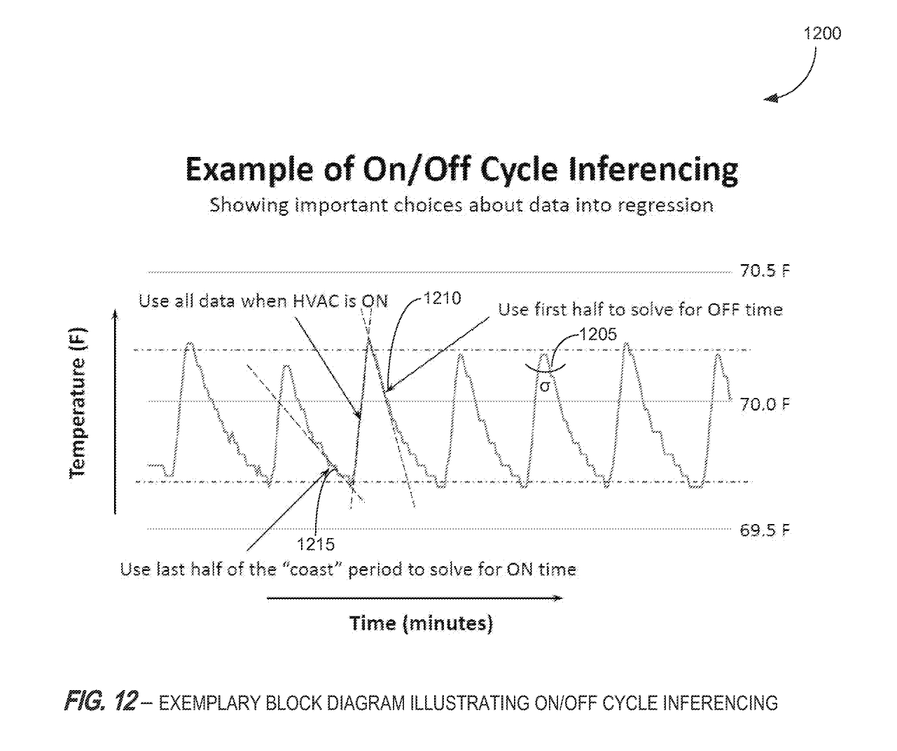

In one aspect, FIG. 12 illustrates exemplary data regression of on and off cycle inferencing, according to one embodiment of the present disclosure. In one aspect, the data for the time when the HVAC system is on (and off) can be used in a linear regression to characterize that part of the cycle. In one embodiment, the present system determines the HVAC cycle (on and off occurrences) by identifying a valid predetermined angle 1205 at the intersection of two linear regressions (or the inflection point). In one embodiment, the predetermined angle 1205 is dictated by the size of the HVAC system.

In one embodiment, a predetermined number of data points before and after the inflection point are ignored from the regression analysis to eliminate noise data and create a more accurate regression. According to one aspect, the ignored points enable the curvature around (i.e., before and after) the inflection point to be eliminated from the linear regression data, which enables an accurate linear regression. In one embodiment, 3 data points (when taken at one-minute intervals) before and after the inflection point are removed to eliminate noise and create a more accurate regression. In another embodiment, a predetermined number of minutes (i.e., 1 minute, 2 minutes, 3 minutes, etc.) of temperature data before and after the inflection is removed to provide a better data sample for the linear regression.

In a further embodiment, using the temperature and time data from the last half of the off period 1215 or coasting period can determine an on and/or off time. In one embodiment, solving for the off time is achieved by using the temperature and time data for the first half 1210 of the off period. In one embodiment, a linear regression is found using a minimum and a maximum of predetermined data. For example, in one embodiment, the linear regression comprises at least 5 minutes of data, but no more than 9 minutes of data. In another embodiment, the liner regression comprises at least 3 minutes of data, but no more than 8 minutes of data. According to one aspect, setting the linear regression equations to equal each other results in an accurate estimate of when the system turns on and off without connecting wires to the existing thermostat terminals. Therefore, the “sensing” method occurs by measuring the ambient temperature (via a TMD), mapping those temperatures to specific time stamps, and determining associated HVAC on and off occurrences based on the collected data. As will be generally understood by one of ordinary skill in the art, the aforementioned exemplary discussions and use cases are not intended to limit the spirit or scope of the present disclosure and it may be intuitive by one of skill in the art to modify the exemplary uses cases.

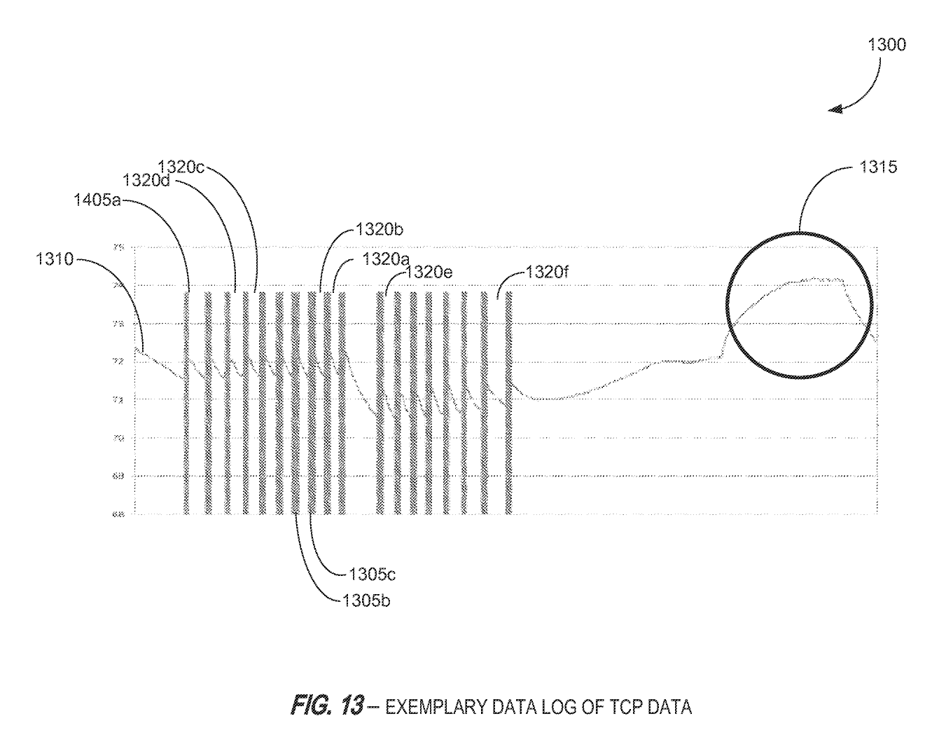

FIG. 13 is an exemplary chart 1300 illustrating the raw minute-by-minute data for a typical day when a heating system is operating, according to one embodiment of the present disclosure. The chart shows a 24-hour period starting at midnight at which time the thermostat was set at around 72° F. and was moved down to 71° F. around 6:00 a.m. The time when the heat came on is shown as a vertical bar 1305 a, b, c indicating the heat was on and does not show at all when the heat was off Around mid-day, the outside air temperature rose high enough that the heat never came back on all day. In one aspect, the solid line 1310 describes the inside ambient temperature associated with the particular building/structure.

A bump or raise in the temperature late in the evening 1315 is shown in FIG. 13. In one aspect, the bump 1315 likely had nothing to do with outside air temperature, but was likely due to TV and lights being on late in the evening. In one aspect, the bars indicating the system being on in each 1 minute logged interval are thickening up 1305b, 1305c in the early morning, as it is getting colder and colder outside. Also, notice that the space between the bars is getting shorter and shorter 1320a versus 1320b, 1320d. Then, as the day warms, one can easily see the space between the bars widening out 1320e versus 1320f illustrating that it takes longer for the house to lose temperature due to the increase in ambient air temperature.

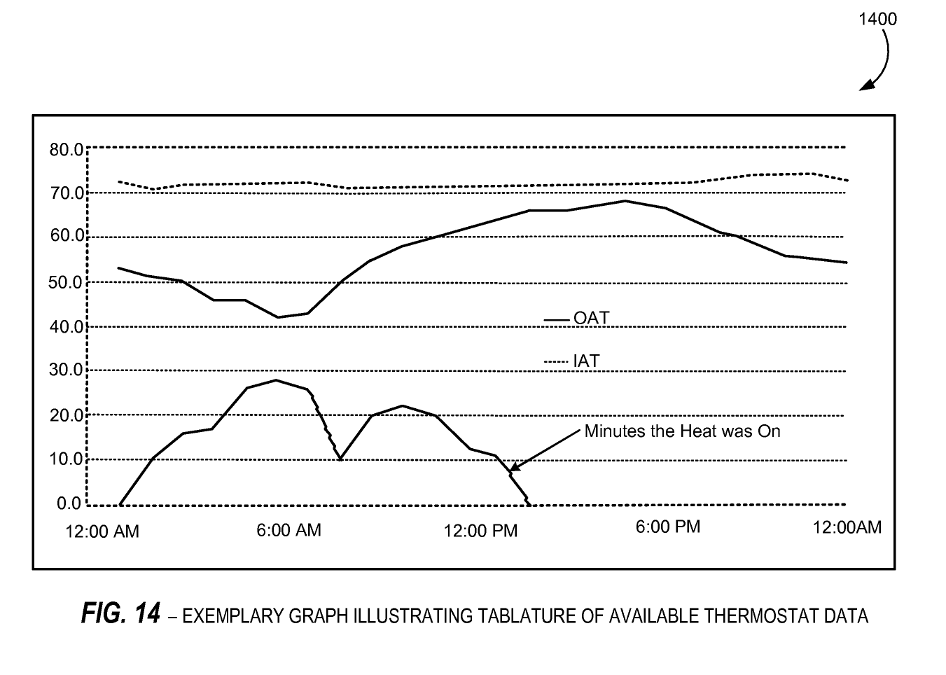

FIG. 14 is an exemplary graph 1400 that illustrates a tablature of all the available data into an hourly summary of how many minutes the heating system was on, what the average internal temperature of the home was, and what the outside air temperature was at the same time for a given structure.

A tabular view of the data from graph 1400 is shown in table 3 and can be the basis for a wide range of analyses. In one aspect shown in table 3, the coldest time of the night resulted in the heat coming on 28 minutes out of the hour. It was 42.1° F. outside and 71.9° F. inside during this period. In one aspect, if the air conditioner had turned on later in the day, that could be shown as well.

According to one aspect, the heating system ran for a total of 219 minutes that day, but the informational value of that total run time is typically low until it is compared to other days and other weather conditions. Generally, it is far more instructive to see it when compared to the indoor and outdoor air temperatures. In one aspect, daily total heating or cooling minutes of system operation can be logged over time and categorized by the temperature set point in the thermostat.

TABLE 3
Exemplary Comparison of Ambient Outdoor
Temperature to Indoor Ambient Temperature

| Hour | Temp F. | Main Living Area | | |
|---|---|---|---|---|
| Ending | Outdoor | Indoor | Heat Min | Cool Min |
| 1:00 AM | 53.1 | 72.1 | 0 | 0 |
| 2:00 AM | 51.1 | 70.6 | 10 | 0 |
| 3:00 AM | 50.0 | 71.8 | 15 | 0 |
| 4:00 AM | 46.0 | 71.9 | 17 | 0 |
| 5:00 AM | 46.0 | 71.9 | 26 | 0 |
| 6:00 AM | 42.1 | 71.9 | 28 | 0 |
| 7:00 AM | 43.0 | 71.9 | 26 | 0 |
| 8:00 AM | 50.0 | 71.0 | 10 | 0 |
| 9:00 AM | 59.0 | 70.9 | 20 | 0 |
| 10:00 AM | 57.9 | 70.9 | 22 | 0 |
| 11:00 AM | 60.1 | 71.0 | 20 | 0 |
| 12:00 PM | 62.1 | 71.0 | 13 | 0 |
| 1:00 PM | 64.0 | 71.2 | 11 | 0 |
| 2:00 PM | 66.0 | 71.0 | 0 | 0 |
| 3:00 PM | 66.0 | 71.2 | 0 | 0 |
| 4:00 PM | 66.9 | 71.5 | 0 | 0 |
| 5:00 PM | 68.0 | 71.8 | 0 | 0 |
| 6:00 PM | 66.9 | 72.0 | 0 | 0 |
| 7:00 PM | 64.4 | 72.1 | 0 | 0 |
| 8:00 PM | 61.0 | 73.0 | 0 | 0 |
| 9:00 PM | 59.0 | 73.8 | 0 | 0 |
| 10:00 PM | 55.9 | 74.1 | 0 | 0 |
| 11:00 PM | 55.0 | 74.1 | 0 | 0 |
| 12:00 PM | 54.1 | 73.1 | 0 | 0 |
| Avg or Tot | 56.8 | 71.9 | 219 | 0 |

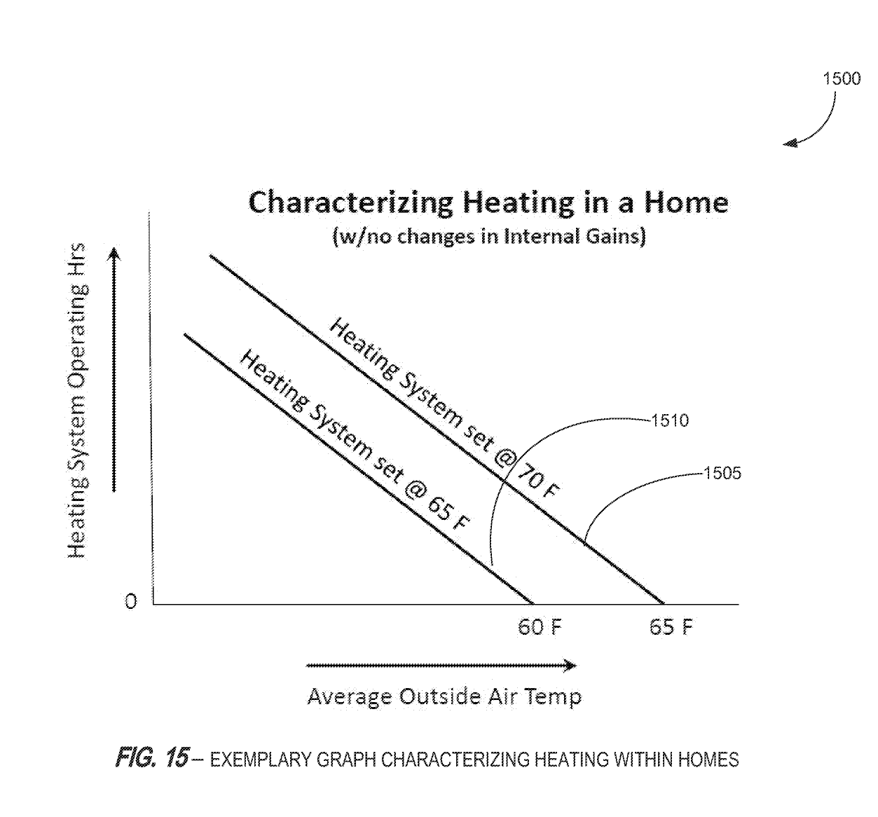

FIG. 15 is an exemplary graph 1500 that emphasizes an assumption the thermal gains that exist in the home (appliance activity, people and pets in the home all day, lights, electronics, etc.) are all consistent during the data analysis period. In one embodiment, the graph 1500 shows that for a temperature set point of 70° F. in the home 1505, the heating system data will go through the zero point of operating hours at about 65° F. That is the most common internal gain result for most American homes and is the reason Heating Degree Days (HOD) are computed in the US based upon a 65° F. basis. In another aspect, if the homeowner were to hold the thermostat at 65° F. 1510, the data would go through a 60° F. temperature point when extrapolated to zero run time for heating.

In one embodiment, the analysis of the off times in the heating and cooling cycles enable a range of new and profound energy analyses. In one aspect, when the home is improved with better insulation and possibly reduced infiltration, the slope of the line 1505,1510 changes. According to one aspect, the speed with which the inside of the house changes should be lower with the improved envelope of the home. According to one aspect, this can be illustrated as the rate of change in degrees per hour.

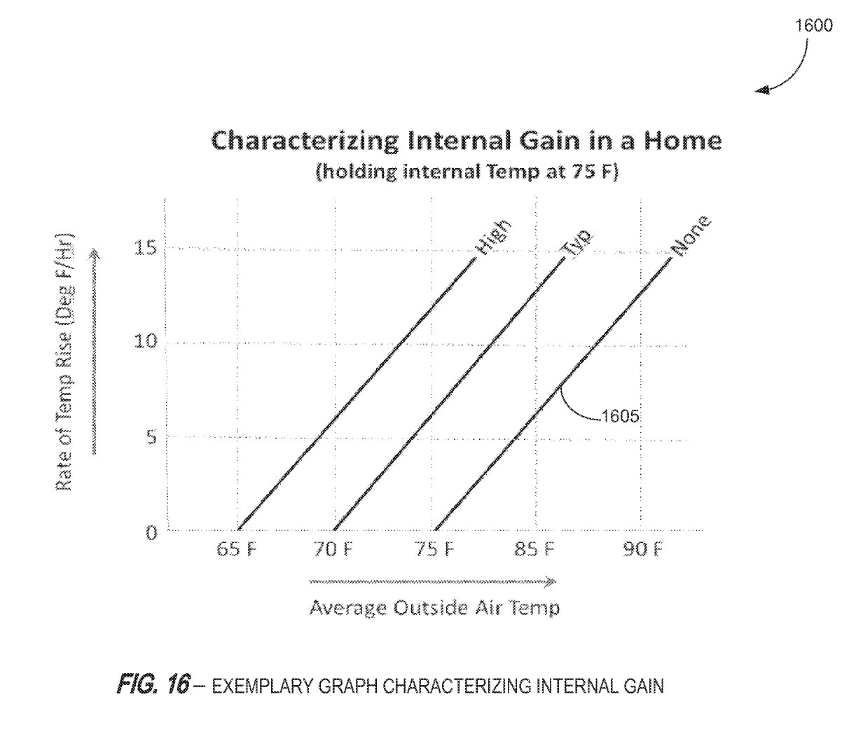

FIG. 16 is an exemplary graph 1600 illustrating a characterization of internal gain in a home, wherein internal gain generally comprises heating of a structure due to internal activities or internal heat sources (TV, bath water, dishwasher, oven, cooking, blow dryer, etc.). In one aspect, if the home is characterized by the rate of temperature rise during the cooling cycles and the rate of temperature fall with the heating cycles in degrees per hour, this is a useful index that can describe home performance. If data is plotted for a home, it will fall neatly into the following graphical framework as shown here for the cooling cycle where the thermostat is set at 75° F. 1605.

In one aspect, the outside air temperature equals the inside air temperature at 75° F. with no rise in the internal home temperature if and when there is no internal gain (literally impossible but a useful limit condition for graphical representation). According to one aspect, many homes have enough internal gain to require some degree of cooling to hold an internal temperature of 75° F. when the outside air is above 70° F. In one aspect, if there was a high level of internal gain (e.g., a party in the house), the situation might require cooling to prevent the temperature from rising above 75° F.

In one embodiment, the rate of temperature rise during the AC off-cycle actually measured in the home for any given outside air temperature and a given internal thermostat setting will fall somewhere on the plot of 1600 and in proportion to the internal gain. Therefore, an index of internal gain can be determined from this plot by using the difference between the path points for a given day on this plot and the zero internal gain reference line. In other words, if the points for any day in question all fall along the typical gain line, the internal gain is relatively constant. If, however, the points in the middle of the night are closer to the zero gain line compared to late in the afternoon when people are up and about and perhaps the Westward-facing glass is picking up a lot of thermal gain, the points will move to the high internal gain line area. Therefore, it is possible to explicitly monitor and measure internal gain.

In one aspect, the temperature change rates during the recovery periods of HVAC operation can quantify things that have historically been problematic to measure. For example, the effectiveness of thermal shielding in the attic using reflective films has never been conclusively measured. The present method can explicitly permit comparison of a home before and after the installation of a reflective coating or material. In other words, if the shielding is working, the thermal gain in the attic would be lower and the degree to which this affects the HVAC system will be explicitly measured using this method.

In one embodiment, if the home is improved by adding insulation and reducing infiltration, these change rates should drop. Alternatively, in another embodiment, if the home is not improved the change rates will remain the same. Further, the HVAC system should be able to heat or cool the house more quickly as well.

In one embodiment, at a given temperature and internal gain level, the rate of change in the home when the HVAC turns off is proportional to the thermal conductivity of the shell (i.e., structure of the home) plus infiltration losses. According to one aspect, if the shell and infiltration are improved, the home should cool off or heat up more slowly at any given temperature difference.

In one aspect, the homes would be monitored for a few weeks or months before the weatherization was started and should then show almost immediate impacts after the weatherization was achieved. In one aspect, if the weatherization did not result in clear and appropriate reductions in the temperature change, it would potentially identify defects in the installation, defaults in the weatherization material/equipment, etc., that may need to be corrected.

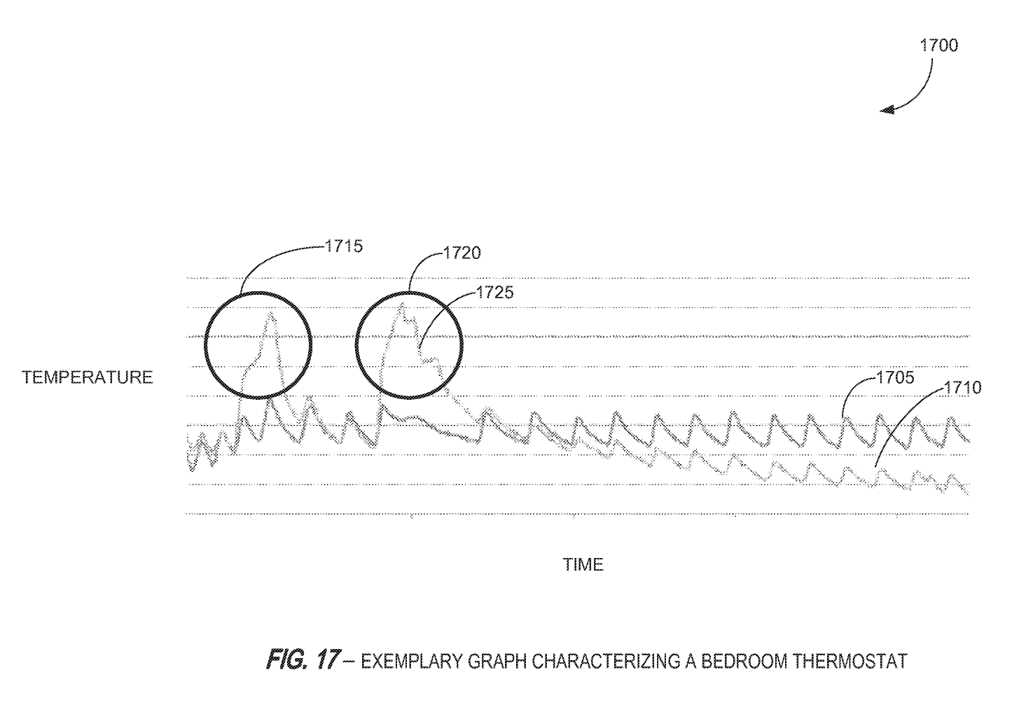

As an illustration of how discomfort can be monitored, consider one example illustrating the way most discomfort is handled by customers. The thermostat is set to 71° F. on a cold winter night and the customer goes to their favorite area to sit, read a book, cook a meal, or watch TV. The thermostat is probably not in their area. It is likely in a hallway or an adjacent room. FIG. 17 shows an exemplary graph 1700 illustrating a bedroom thermostat with the simultaneous recordings from the adjacent bathroom on just one evening. In one aspect, the horizontal lines are 0.5 degrees F. apart. The first line 1705 is the bedroom thermostat, which was moved up a bit when the occupants were retiring for the evening. In one aspect, it is shown in FIG. 17 that the on/off bistable for this thermostat is approximately 0.6° F. The bedroom thermostat setting was kept constant as shown. According to one aspect, the second line 1710 is another thermostatic monitor left in the bathroom adjacent to the bedroom. In one aspect, the rise 1715 in the second line 1710 shows something added to the thermal gain in that room. In one example, a user went in the particular room to iron some clothes. The combination of the iron operation and the lights added several degrees to the local reading. In another aspect, as shown in FIG. 17, approximately two hours later, another family member went in and ran a hot bath. It is shown that the bath warmed the bedroom area 1720. FIG. 17 illustrates that the heat losses diminish during that period of time due to the negative temperature slope loss. The customers go to sleep after the bath as it is shown that the bathroom area gradually drifts to lower and lower temperatures overnight, and there was no longer any heat-gain in that room. By early morning, it is shown that it is a full degree F. cooler in that room. As will be generally understood, the aforementioned exemplary discussion was not intended to limit the spirit or the scope of the present disclosure.

In one embodiment, a building can be characterized during the night and during the day. It can also be shown how afternoons with full sun might compare to afternoons when it was the same temperature but was overcast. That would prove how much that solar gain affects the cooling system operation.

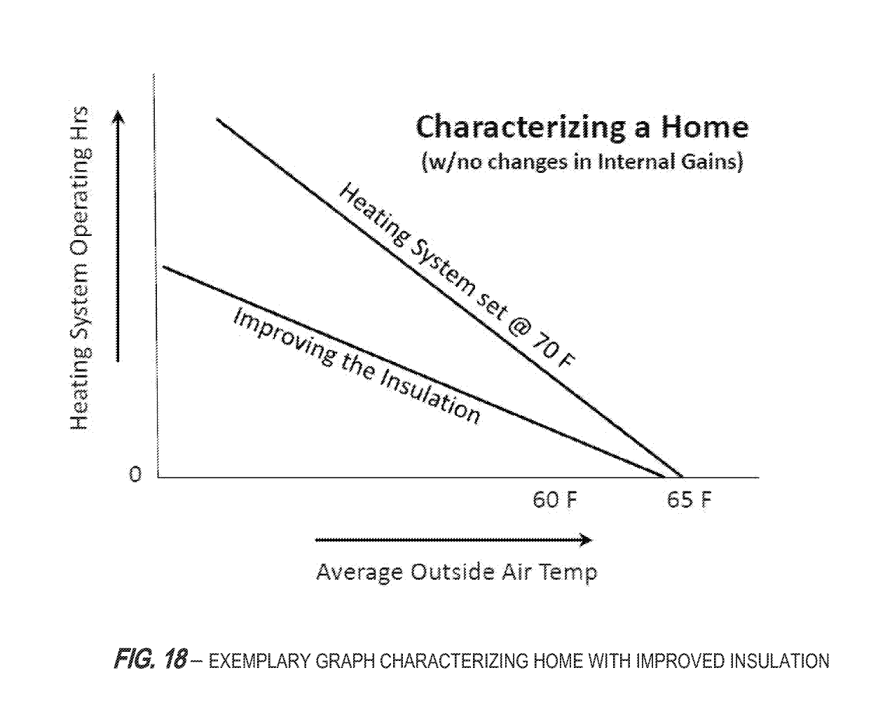

In one aspect, measuring the TCP characteristics before and after a retrofit of insulation measures will enable a determination of retrofit efficiency. In one aspect, it is known what the temperature setting was before the improvements and has characterized the slopes for the rises and falls as shown in connection with FIG. 18. Accordingly, if the insulation and infiltration were truly effective (and one did not disturb the supply and return air balance that negated all of these improvements), much greater rapid rises when the heat turns on and much lower slopes for the temperature fall when the heat was off would be expected. In summary, the heating system should not run as often as it did prior to the insulation of the improvement measures.

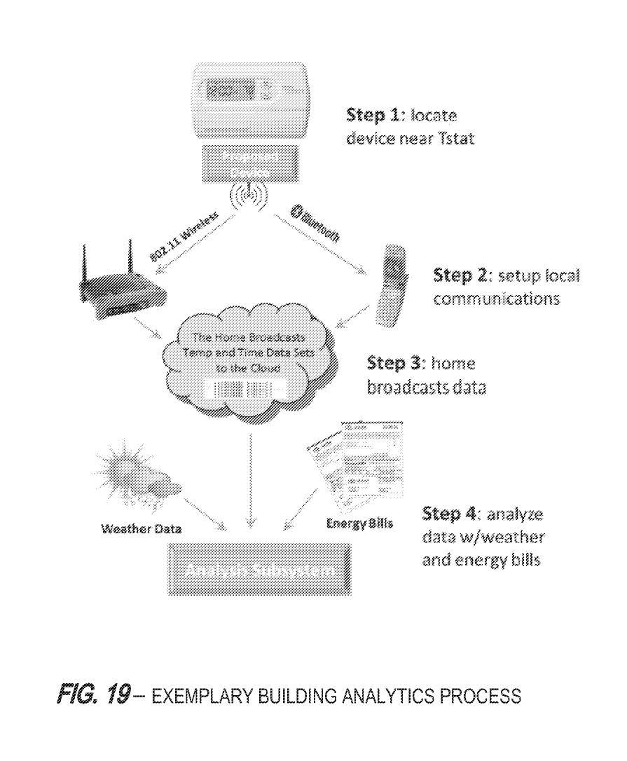

FIG. 19 illustrates one embodiment of the manner in which the proposed device and analysis method are implemented. As shown in step 1, and in one embodiment, the resident would not wire the thermostat monitoring device (TMD) directly to the existing thermostat to detect the on and off cycles, but would most likely simply locate the device(s) near the existing thermostat(s). Specifically, in one embodiment, the TMD simply records accurate temperature and time readings from the ambient environment, and these temperature readings (which are typically mapped to specific times, time intervals, etc.) can be interpreted as on and off cycles of the HVAC unit based on the changes in the readings over time. In another embodiment, the TMD is wired directly (or otherwise operatively coupled) to the existing thermostat to identify when the HVAC turns on and off.

As shown in step 2, local communications are established by logging the TMD onto either a cell phone, a local wireless network, a USB hub, Bluetooth, RJ45 cable, or any other communicating mechanism. In one aspect, the proposed device has a further option in which the device writes the records (temperature data) to micro SD cards that can then be mailed to the sponsoring energy companies to document the thermostat behaviors and receive economic credit for having done so. In one embodiment, the TMD transmits the temperature data/records to the cloud for remote storage.

In one embodiment and as shown in step 3, the home broadcasts each day's thermostat temperature and time records to a data repository in the cloud, database, server, etc., and data is stored under that customer's unique identifiers for their home and thermostat location. Therefore, one embodiment, the residents/homeowners would have separate data streams coming from each thermostatic device. In one embodiment, the transmissions would generally be automatically scheduled between some predefined low usage time period, such as 1:00 a.m. and 3:00 a.m. In another embodiment, the transmissions may occur in real time. In another embodiment, the transmissions may occur according to a predefined time.

As shown in step 4, the overarching system analyzes the transmitted data on servers in the cloud environment or similar data storage mechanism and merges the resident's data with local hourly weather data along with customer energy bills and/or smart grid interval data (e.g., available through Green Button protocols). In one aspect, at this point, the daily “traces” of thermostat on/off temperature and time behavior can support numerous derivative analytical methods that in turn answer operational performance questions or provide operational proof of the resident's behaviors. Certain embodiments of the detailed methods use are documented in this submittal but can be summarized into broad range of information management.

In one embodiment, the overarching system may analyze data associated with home thermal performance assessments. In one aspect, documenting how the home's walls, ceiling, floors, windows, etc. perform in response to weather and thermostat temperature settings and quantifying how and to what extent improvements have been made to that performance. In one embodiment, the overarching system may analyze data associated with HVAC performance assessment. In one aspect, the system documents how the HVAC system operates now in response to weather and thermostat temperature settings and quantifying how and to what extent improvements have been made.

In one embodiment, the overarching system may analyze data associated with internal gain assessments. In one aspect, many comfort problems are associated with high thermal gains (Westward-facing glass, infiltration problems, air migration, etc.). The present system can identify and dynamically indicate internal gain levels intuitively so that customers can identify and correct the causes of their discomfort. In one embodiment, the overarching system may analyze data associated with dynamic pricing without interval meters. In one aspect, the electric utility industry has struggled with ways to be sure customers can and do respond to prices and change behaviors. The present system can confirm customer actions in response to price signals even if the utility has only traditional monthly meter read intervals.

In one embodiment, the overarching system may analyze data associated with dynamic price offer origination. In one aspect, the analysis methods presented here permit customized program offers to customers based upon the way their home responds to weather and thermostat settings. Therefore, it is possible to dynamically calculate how a system in a home would react on a peak hot or cold day and to then personalize offers to customers based upon their proven capability. In one embodiment, the overarching system may analyze data associated with contractor/energy auditor assessment. The present system and methods permit an insightful and helpful review of a customer's home performance situation that goes far beyond gross measures such as blower door tests. The actual performance of a home can be studied by professionals and used to assist and confirm a customer's improvements.

### Exemplary Thermostat/Temperature Monitoring Device

Provided below is a discussion of an exemplary thermostat/temperature monitoring device (TMD), according to one embodiment of the present disclosure. As will be generally understood by one of ordinary skill in the art, variations of other types of components and hardware aspects are possible. Further, various other features associated with a TMD may also be possible and the following description is not intended to limit the spirit or the scope of the present disclosure.

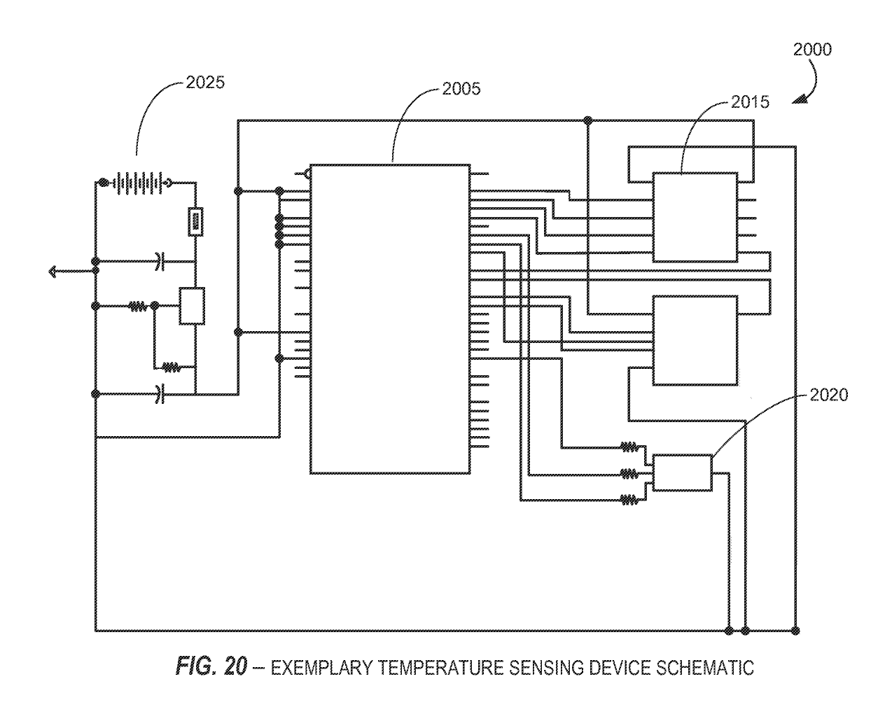

FIG. 20 illustrates an exemplary thermostat/temperature monitoring device (TMD) 2000, according to one embodiment of the present disclosure. As previously described, in one embodiment, the TMD 2000 may be placed near a thermostat and records ambient temperatures with associated timestamps for determining various analytics associated with a structure's energy efficiency. In another embodiment, the TMD 2000 may be operatively coupled to a structure's thermostat to record various thermostat operation data in association with determining various analytics in connection with a structure's energy efficiency.

In one embodiment, a thermostat/temperature monitoring device (TMD) 2000 is designed to collect and analyze an HVAC system's usage data from a given residential climate zone. Through the use of a high-performance microprocessor 2005 (as shown in FIG. 20), combined with a high-accuracy temperature sensor 2010, the TMD 2000 is able to capture and record detailed data about the fluctuating temperature in a room. By plotting individual data points, equipped with their own individual timestamps, on a graph, the analysis engine can then determine aspects about a customer's residence, as well as his or her energy use regarding the following: total HVAC system runtime, set heating temperature, set cooling temperature, relative efficiency of HVAC units, effectiveness of residential insulation, etc.

In one aspect, the resulting analytics exercised on the data can also be used to determine a host of other important analytics regarding a customer's specific home energy profile. In addition to energy logging, the TMD 2000 can be used to aid and assist utility companies in a variety of verification and eligibility programs. In one aspect, the overarching system analytics may assist with home insulation rebate verification. In one aspect, comparison of the temperature datasets collected before and after application of new in-home insulation can verify the effectiveness of the new insulation, while allowing the utility company to unobtrusively determine the customer's eligibility for a rebate on the new insulation upgrade.

In one aspect, the overarching system analytics may assist with new HVAC auditing. In one aspect, analysis of a specific temperature dataset can aid a utility company's energy auditing representative to determine whether the customer's current HVAC system is of optimal capacity for the home in question, thereby enabling him or her to make proper recommendations regarding the specifications for a replacement system.

In other embodiments, the TMD 2000 can further be used to aid and assist utility companies for energy-saving pledge verification. Typically, utility companies offer rebates for customers who pledge to change their energy usage habits by changing their thermostat settings to use less energy. By installing a TMD 2000, and cross-referencing its data with a customer's existing billing data, the utility company can verify that the customer has indeed properly modified his or her thermostat settings, and is maintaining the pledge. All of this functionality is contained within an unobtrusive, small form factor device, which is designed (in one embodiment) to be placed atop or near a customer's thermostat. The TMD operates completely silently and autonomously, allowing it to collect the proper data without the need for the customer to extensively interact with it. In other embodiments, the TMD may be placed in a location within the structure that is not near a thermostat.

In one embodiment, the TMD 2000 is driven by a microprocessor 2005 such as an Atmel's ATmega32U4 microcontroller chip. In one embodiment, the microprocessor collects and processes data received from the other components within the device. In one aspect, the microprocessor 2005 stores analysis and storage protocols for the associated temperature data. In one embodiment, the microprocessor 2005 comprises an analog to digital converter, for measuring external signals, an internal clocking mechanism, self-programming memory, with a JTAG interface for easy device debugging and customization, on-chip encryption support, and a low power requirement.

In one embodiment, the TMD 2000 comprises an integrated circuit (IC) capable of accurately measuring the temperature of a residential climate zone, so as to be able to produce an accurate set of data upon which to perform calculations. In one embodiment, the IC comprises a sensor 2010 with an adequate sensor resolution to detect fine incremental changes over time, thus building a more complete dataset. In one embodiment, the IC comprises sensor accuracy, with adequate variation in temperature readings, to preserve the overall accuracy of the dataset, and eliminate erroneous readings. In one embodiment, the IC comprises low operational current draw, to preserve the device's battery power and allow for long operational periods without recharging. In one embodiment, the IC comprises relatively low “shutdown” current draws, in order to preserve the device's battery power while inactive. In one embodiment, the IC comprises a low operational voltage, in order to be compatible with the voltage requirements of the TMD's main microprocessor 2005. In one embodiment, the IC comprises a mechanism for communicating temperature data from the device to the data storage mechanism via a data bus through the main microprocessor 2005.

In one embodiment of the TMD 2000, the sensor 2010 comprises a TMP 112 sensor 2010, manufactured by Texas Instruments. In one embodiment, the sensor 2010 is capable of detecting temperature changes as small as 0.0625 degrees Celsius, a degree of accuracy that is more than acceptable for use in a residential logging and control situation. In addition, the device exhibits a relative accuracy of plus or minus 0.2 degrees Celsius on average, which proves to be higher than that of the average residential thermostat. In one aspect, the sensor 2010 comprises a maximum current draw of 1.0 μA, and a standby draw of less than 1 μA. In one aspect, the sensor 2010 can store pre-set temperatures in memory, and add an alert in the log once the measurements have been exceeded. In one aspect, said functionality enables energy auditing, or identification of anomalous conditions in a particular climate zone. As will be generally understood, the aforementioned performance characteristics are for exemplary purposes only and are not intended to limit the spirit or the scope of the present disclosure.

In one embodiment, the TMD 2000 possesses a simplistic, easily replaceable power supply, which does not require the use of nonstandard adapters, batteries, voltage levels, etc. In one embodiment, the TMD records data over the span of several days, to several weeks, to relatively anytime such that the TMD 2000 produces an accurate “picture” of a customer's energy consumption profile. In one embodiment, the TMD includes an AC power adapter.

In one embodiment, of the TMD 2000 uses a standard 9-volt, user-replaceable alkaline battery 2025. In one aspect, under typical operating conditions, the components of the device, the microprocessor 2005, temperature sensor 2010, and SD card reader 2115, exhibit the following levels of overall current draw displayed in table 4.

TABLE 4
Exemplary Current Draw of the Various TMD Components

| Device | Typical Draw (μA) | Maximum Draw (μA) |
|---|---|---|
| ATmega32U4 | 1-5 | 5000 |
| TMP112 | 1 | 10 |
| Micro SD Reader | 250* | 100000 |

*Only exhibited when the device is in an idle state. Typically, the reactor will be powered off.

In one embodiment, the microprocessor 2005 draws up to 5 mA while in “Active” operation, averaged over the span of one second, the data collection subroutine will limit the processor to a reduced “idle” mode for intervals of 15-60 seconds at a time. In another aspect, condensing processor bursts to very small intervals (only active when a temperature reading needs to be taken), current costs can be dramatically reduced.

In one embodiment, the Micro SD reader can draw up to 100 mA while engaged in a read/write operation, but special optimizations can be put in place to ensure that it only makes a write once every 20-60 minutes. Typically, in one aspect, the SD standard dictates that Micro SD cards are broken up into 512-byte sectors. Each data point collected by the thermal sensor 2010 amounts to approximately 10-12 bytes of data. By holding data in processor memory until a full block is accumulated, writes to SD can be limited to approximately one per every one hour. As will be generally understood, the aforementioned discussion in connection with the various components is for exemplary purposes and is not intended to limit the spirit or the scope of the present disclosure. With the preceding facts in mind, an average current draw for one embodiment of the device's overall operation appears in table 5.

| Device | Average Draw (μA) |
|---|---|
| ATmega32U4 | 5 |
| TMP112 | 1 |
| Micro SD Reader | 250 |
| Total | 256 |

### Table 5 Exemplary Average Current Draw of TMD Components in Operation

Given an average consistent current draw of approximately 256 μA, an estimate of the device's battery life can be calculated, as follows:

$$Typical life of 9 V alkaline battery = 580 mAh$$

$$256 μ Ah current draw * 1 hour = 256 μ Ah consumption per hour$$

$$\frac{256 μ Ah}{1 hour} \times \frac{1 μ Ah}{1000 mAh} = \frac{.256 μ Ah}{hour} consumption rate$$

$$580 mAh max capacity \times \frac{1 hour}{.256 μ Ah} \times \frac{1 day}{24 hours} = 94.401 days of battery life$$

In one embodiment, the TMD is able to provide 94 days of targeted battery life before the battery will need to be changed. As will be generally understood, the aforementioned battery life is for exemplary discussion only and is not intended to limit the spirit or the scope of the present disclosure.

In one embodiment, power to the TMD 2000 is controlled through the use of a singular single pole-single throw on/off microswitch. In one aspect, the microswitch is accessible through a cutout in the device's enclosure, allowing its actuation without the need to open the external casing. In one aspect, by using this mechanism, the device can be shipped to the end-user with the battery pre-installed, ensuring that minimal effort is required to set up and activate the TMD. In other embodiments, the on/off mechanism may comprise a push button, a solar powered turn on mechanism, etc.

In one embodiment, once powered on, the TMD operates on a 100% positive duty cycle, remaining in continuous operation until either the power switch is switched off, or the battery is fully discharged. In one embodiment, it is not necessary (although it is possible) for the device to have a complicated graphical user interface (GUI), external display screen, or interactive controls. It is prudent, however, to ensure that some type of notification appliance is integrated into the device, in order to alert the end-user to anomalous operating conditions and errors, as well as to confirm that the device is functioning normally.

In one embodiment, a single 5 mm tri-color light-emitting diode (LED) 2020 is integrated into the device's circuitry. The microprocessor 2005 natively supports several pulse width modulation pins which, when connected to the three cathodes of the LED 2020, enable the singular LED 2020 to broadcast over 16 million different color combinations. In addition to the inherent simplicity of this function, which ensures that customers from a host of different cultures, languages, and backgrounds can use the device without the need for language localization, the use of an LED 2020 requires a substantially lower amount of current, thereby preserving the battery life of the device as a whole.

In one embodiment, the LED 2020 is programmed to emit the following signals, depending on the current device state and/or error condition. Some exemplary signals are described below:

Solid GREEN, 5 s in duration: Denotes a successful self-test. This condition will clear automatically, as the device begins standard operation.

Solid AMBER: Shown in the device's power-up sequence, this condition indicates that the device is testing its individual sensor 2010s, data storage access, and communication abilities. This condition will persist until the self-test is completed.

Solid RED: Denotes a critical failure in one of the device's components, which could include the temperature sensor 2010, communication chips, data storage device, or microprocessor 2005. This may be shown at the end of a self-test sequence if one or more diagnostic tests fail. This condition will also be shown if a micro SD card (if needed) is not inserted in the proper socket.

Single GREEN flash, 0.2 s in duration: Denotes a successful capture of a temperature data point. The interval of data capture can be specified by either the utility company or the customer upon device programming, ranging at intervals between 15 s and 1 m.

Single AMBER flash, 0.2 s in duration: Denotes a successful capture of a temperature data point, with the device detecting a “low” battery level (approximately 30% of the nominal voltage remaining)

Single RED flash, 0.2 s in duration: Denotes a successful capture of a temperature data point, with the device detecting a “critical” battery condition (approximately 12% of the nominal voltage remaining)

Rapid BLUE flashes, 0.1 s on, 0.1 s off: The device is transmitting data to the information server through one of its two communication chips. This condition will persist until the transmission is complete.

Rapid AMBER flashes, 0.1 s on, 0.1 s off, persisting for approximately 5 s: The device is unable to connect to a local wireless network or Bluetooth device. Data storage will take place on the device only.

Rapid RED flashes, 0.1 s on, 0.1 s off: The device's data storage card is full. No more data can be collected.

In one embodiment, the data collected by the TMD 2000 is also stored. Typically, in one embodiment, devices of this category utilize some type of internal storage mechanism (usually flash- or solid-state memory chips) to store data collected, which can later be offloaded via a Universal Serial Bus (USB) connection. In another aspect, utilizing a series of on-chip data structures to contain the logging data collected by the TMD 2000, the device utilizes a Micro SD-centric storage system. By utilizing a serial peripheral interface bus (SPI) functionality inbuilt into the microprocessor 2005, the card system can interface with the rest of the device through a simple four-pin connection, leaving the rest of the processor to perform other tasks.

In one embodiment, on device startup, the processor polls the Micro SD reader to determine whether a card is present. In one aspect, if no card is inserted in the reader, the processor throws an error condition, which prevents the system from recording temperature data until the end-user inserts a compatible card. In another aspect, once the card is in place, the system will run a brief scan of the card, in order to determine whether or not it is of a compatible type and size. Once complete, the processor will return to a normal operating mode. As will be generally understood by one of ordinary skill in the art the aforementioned discussion is for exemplary purposes only and is not intended to limit the spirit or scope of the present disclosure.

In one aspect, in an idle state, the card reader can draw up to 250 μA of current, with read/write operations consuming up to 100 mA, averaged over a one-second period. While this is normally not a significant impediment in devices that are designed to be recharged frequently, such as smartphones and cameras, this type of usage can dramatically reduce the expected runtime of the TMD 2000. As a result of this, the processor has been specially programmed to utilize a “batch writing” functionality, in which a portion of logged temperature data is retained on-chip until enough has been accumulated to write to the card for permanent storage.

Generally, cards in the SD family possess a sector size of 512 bytes. Writing a single sector contiguously, and all at once, consumes far less power than repeated writes to a card, spanning multiple sectors. In one embodiment of the TMD 2000, a single data point collected by the temperature sensor 2010, and tagged with the proper timestamp, consumes approximately 16 bytes of storage space. In one aspect, to optimize power usage, the microprocessor 2005 is programmed to retain 32 individual data points within its own internal memory, before making a write to the card. In this manner, instead of writing to the card once every minute (assuming factory-default settings), the device will only write to the card once every 32 minutes, increasing the efficiency of the device and its power usage. In one aspect, in between writes, the card reader will be powered off instead of remaining idle, further increasing the TMD's overall battery endurance.

In one aspect, the TMD 2000 utilizes its own proprietary form of on-chip encryption. When verifying an energy audit or rebate eligibility, it is imperative to the utility industry that a customer provides fair and accurate data. Fraudulent data reporting can result in revenue loss, improper analytics, and can negatively affect utility operation. In addition, it is important to the customer that his or her data is protected while undergoing the collection and processing phase, and remains uniquely tied to his or her own energy profile.

In one embodiment, the TMD 2000 encrypts each individual device with a unique identifier, tied to the individual customer. In one aspect, encryption is performed with each data write, and the resulting log files can only be decrypted by providing a unique identifier on the server-side system. In order to ensure proper operation of the device, it is created with a custom-crafted printed circuit board (PCB). The board utilizes silver leads that are RoHs compliant, to ensure data capture reliability and device longevity. In one embodiment, the microprocessor 2005, temperature sensor 2010, and Micro SD reader are all surface-mounted directly to the board, to reduce the risk of frayed or broken connections, while allowing easy, single-piece replacement in the event of a component failure. Generally, the board is also silkscreened, to allow for easy identification of components and connections in the event that a repair is deemed necessary.

In one embodiment, the enclosure is manufactured using acrylonitrile butadiene styrene (ABS) plastic. This type of material possesses a high grade of impact and heat resistance, while exhibiting a visually attractive appearance. In one embodiment and in addition, this type of plastic can be pigmented to produce a variety of colors, in order to match a customer's preference or home decor.

In on embodiment, the enclosure is designed to be composed of two specific pieces: one piece is designed to contain the main logic board and sensors 2010, and the other is designed to contain the battery. In one embodiment, each piece is 2.75 inches in length, and 1.20 inches in width. The enclosure's top half is 0.44 inches in height, while the enclosure's bottom half has a height of 0.47 inches. Each half possesses 0.1-inch fillets around all contours and edges, except for the lip-and-groove edges that join the two components together. It will be understood by those of ordinary skill in the art that the measurements and form factors suggested herein are provided for exemplary purposes only, and are not intended to limit the scope of the present disclosure.

In one embodiment, the two pieces are designed to be joined together with a simple snap closure, facilitating easy access to the battery for changing, as well as easy access to the logic board for processor programming. In one embodiment, the bottom half also possesses three distinct cutouts for the Micro SD card, status LED 2020, and on/off switch, respectively.

In addition to the component cutouts, in one embodiment, the enclosure possesses individual venting slots near the battery and voltage regulator, allowing any residual heat to escape without compromising the measurements obtained by the temperature sensor 2010. The temperature sensor 2010 is located just behind an additional array of circular cutouts, in order to provide the sensor 2010 with a clean flow of air from the room in which the device is placed.

In one embodiment, the main logic board is secured inside of the lower half of the enclosure through the use of two small retention screws, mounted in securing holes on the bottom half of the enclosure. In this manner, the Micro SO reader, on/off switch, and status LED 2020 are all precisely positioned relative to their respective slots and cutouts on the enclosure's external surface. This placement allows for easy customer interaction. The 9V battery 2025 is secured in the top half of the enclosure through the use of a simple spring clip. This method allows the battery to remain isolated from the remainder of the circuitry, preventing any heat from its discharge from interfering with the internal temperature logging sensor 2010. The battery is connected to the board using a standard connection and two lead wires.

As stated previously, the TMD 2000 uploads data to a mathematical analysis engine for processing. In one certain embodiments, this process can be completed using various methods, which are highlighted in FIG. 1, and detailed below: In one embodiment, data transfer is executed via a Micro SD card. In one embodiment, the data is transferred to the cloud via wireless (e.g., Wi-Fi, Bluetooth, cellular data, etc.) transmission, wherein the data is stored in a remote database, but data may be accessed via the an API. In one embodiment, wireless data transfer to the cloud, data written on an SD card, and wired data transmission comprise data encryption from the main microprocessor 2005, and the data will be protected from tampering.

In other embodiments, the TMD 2000 is augmented with a low power, high-efficiency 802.11 n wireless chip. Instead of requiring a customer or auditor to extract the Micro SD card for data processing, the Wi-Fi chip will enable the TMD 2000 to interface with a customer's home network, directly uploading captured data to the processing servers at pre-set intervals. The transmitted data will still retain its encrypted properties, thereby preventing it from being modified while in transmission. In addition, the encryption will protect against the unwilling release of customer information broadcast in the data stream.

To further augment the device's connective capabilities, in some embodiments it is equipped with a Bluetooth Low Energy (LE) module. Through the use of this low-power protocol, the TMD can transmit data to the processing servers through the use of a customer's laptop computer, smartphone, tablet, or other Bluetooth LE-equipped device, through the use of an easy-to-use mobile application. In this manner, the device can be permitted to upload its data directly, even if the customer does not possess an operational 802.11 wireless network in his or her residence.

In addition to the ease of uploading that Bluetooth LE affords, a companion mobile application can also be used to directly examine the data that has been collected, and its resulting analysis, without the need to log into a home computer terminal. From this portal, the customer can change his or her pledge settings, verify TMD 2000 settings and operation, and receive helpful energy-saving recommendations presented after his or her data has been analyzed.

Besides its use as a logging device, embodiments of the TMD 2000 also have the capability to be upgraded for use as a full thermostat control device. Through the use of a single module attached to a series of breakout pins on the printed circuit board, the TMD can gain a multi-wire control interface, which allows the processor to directly integrate with a customer's pre-existing thermostat. By employing a small voltage regulation and amplification circuit, the TMD 2000 can be used to override the existing thermostat, switching on and off the system at the proper temperature settings dictated by the customer in his or her online profile. These settings can be changed online, or with the use of the mobile application, and are automatically transmitted to the device on its next data upload.

In other embodiments, the TMD 2000 can be used to replace a resident's existing thermostat. In these embodiments, the existing thermostat will be replaced with a smart TMD that enables all of the above-described functionality.

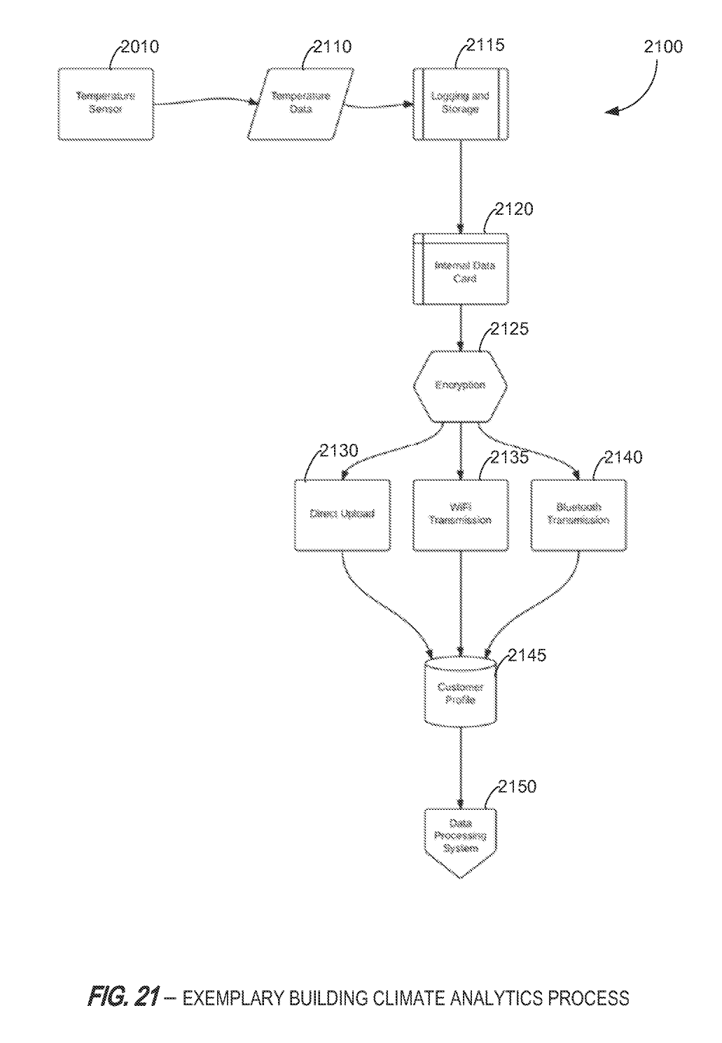

FIG. 21 is an exemplary block diagram 2100 describing the process of capturing and analyzing temperature and thermostat data utilizing a TMD, according to one aspect of the present disclosure. In one embodiment, the temperature sensor 2010 captures temperature measurements at predetermined time intervals (e.g., every 1 second, 5 seconds, 10 seconds, 1 minute, etc.) and associates the temperature data 2110 with a time stamp. In one embodiment, the temperature data 2110 and associated time stamp 2115 logged and stored within the internal data card 2120. As previously described, the temperature data maybe stored on an internal memory, a SD card, a micro SD card, or may be stored within internal random access memory (RAM) and transferred to a larger data repository in real time.

In one embodiment, the temperature data 2110 is encrypted 2125 for further data protection. After the temperature data is encrypted, it is transferred to a customer profile 2145. In one embodiment, the data is stored on a SD card and the data is uploaded via an object upload 2130. In another embodiment, the temperature data is transmitted via Wi-Fi transmission 2135 to the customer profile 2145. In another embodiment, the temperature data 2110 is transmitted via Bluetooth 2140 to the customer profile. In one embodiment, the customer profile 2145 is stored in a database.

In one embodiment, the data processing system 2150 correlates and analyzes the temperature data 2110 creating the aforementioned data regressions to determine the heating/cooling cycles. Further and in one embodiment, the data processing system 2150 can correlate the customers temperature data 2110 with their energy usage to further analyze and determine the impact the HVAC system has on the customer's energy usage.

Aspects of the present disclosure generally relate to devices and methods for capturing the time and temperature at which a thermostat(s) in a structure (i.e., residential home, multi-family home, commercial building, etc.) turns on and turns off, and then analyzing those times and temperatures at particular granularities to identify improvements in energy usage. These time and temperature data points are some of the useful information needed to determine two performance attributes in the structure: the ramping time when the HVAC system is returning the home to the comfort setting (which is called herein the “system on time”), and the ramping time for the home to hit the next on cycle or the “system of time”.

Accordingly, it will be understood that various embodiments of the present system described herein are generally implemented as a special purpose or general-purpose computer including various computer hardware as discussed in greater detail below. Embodiments within the scope of the present disclosure also include computer-readable media for carrying or having computer-executable instructions or data structures stored thereon. Such computer-readable media can be any available media that can be accessed by a general purpose or special purpose computer, or downloadable through communication networks. By way of example, and not limitation, such computer-readable media can comprise physical storage media such as RAM, ROM, flash memory, EEPROM, CD-ROM, DVD, or other optical disk storage, magnetic disk storage or other magnetic storage devices, any type of removable non-volatile memories such as secure digital (SD), flash memory, memory stick etc., or any other medium which can be used to carry or store computer program code in the form of computer-executable instructions or data structures and which can be accessed by a general purpose or special purpose computer, or a mobile device.

When information is transferred or provided over a network or another communications connection (either hardwired, wireless, or a combination of hardwired or wireless) to a computer, the computer properly views the connection as a computer-readable medium. Thus, any such a connection is properly termed and considered a computer-readable medium. Combinations of the above should also be included within the scope of computer-readable media. Computer-executable instructions comprise, for example, instructions and data, which cause a general-purpose computer, special purpose computer, or special purpose-processing device such as a mobile device processor to perform one specific function or a group of functions.

Those skilled in the art will understand the features and aspects of a suitable computing environment in which aspects of the disclosure may be implemented. Although not required, the inventions are described in the general context of computer-executable instructions, such as program modules or engines, as described earlier, being executed by computers in networked environments. Such program modules are often reflected and illustrated by flow charts, sequence diagrams, exemplary screen displays, and other techniques used by those skilled in the art to communicate how to make and use such computer program modules. Generally, program modules include routines, programs, objects, components, data structures, etc. that performs particular tasks or implement particular abstract data types, within the computer. Computer-executable instructions, associated data structures, and program modules represent examples of the program code for executing steps of the methods disclosed herein. The particular sequence of such executable instructions or associated data structures represent examples of corresponding acts for implementing the functions described in such steps.

Those skilled in the art will also appreciate that the invention may be practiced in network computing environments with many types of computer system configurations, including personal computers, hand-held devices, multi-processor systems, microprocessor based or programmable consumer electronics, networked PCs, minicomputers, mainframe computers, and the like. The invention is practiced in distributed computing environments where tasks are performed by local and remote processing devices that are linked (either by hardwired links, wireless links, or by a combination of hardwired or wireless links) through a communications network. In a distributed computing environment, program modules may be located in both local and remote memory storage devices.

An exemplary system for implementing the inventions, which is not illustrated, includes a general-purpose computing device in the form of a conventional computer, including a processing unit, a system memory, and a system bus that couples various system components including the system memory to the processing unit. The computer will typically include one or more magnetic hard disk drives (also called “data stores” or “data storage” or other names) for reading from and writing to. The drives and their associated computer-readable media provide nonvolatile storage of computer-executable instructions, data structures, program modules, and other data for the computer. Although the exemplary environment described herein employs a magnetic hard disk, a removable magnetic disk, removable optical disks, other types of computer readable media for storing data can be used, including magnetic cassettes, flash memory cards, digital video disks (DVDs), Bernoulli cartridges, RAMs, ROMs, and the like.

Computer program code that implements most of the functionality described herein typically comprises one or more program modules may be stored on the hard disk or other storage medium. This program code, as is known to those skilled in the art, usually includes an operating system, one or more application programs, other program modules, and program data. A user may enter commands and information into the computer through keyboard, pointing device, a script containing computer program code written in a scripting language or other input devices (not shown), such as a microphone, etc. These and other input devices are often connected to the processing unit through known electrical, optical, or wireless connections.

The main computer that affects many aspects of the inventions will typically operate in a networked environment using logical connections to one or more remote computers or data sources, which are described further below. Remote computers may be another personal computer, a server, a router, a network PC, a peer device or other common network node, and typically include many or all of the elements described above relative to the main computer system in which the inventions are embodied. The logical connections between computers include a local area network (LAN), a wide area network (WAN), and wireless LANs (WLAN) that are presented here by way of example and not limitation. Such networking environments are commonplace in office-wide or enterprise-wide computer networks, intranets and the Internet.

When used in a LAN or WLAN networking environment, the main computer system implementing aspects of the invention is connected to the local network through a network interface or adapter. When used in a WAN or WLAN networking environment, the computer may include a modem, a wireless link, or other mechanisms for establishing communications over the wide area network, such as the Internet. In a networked environment, program modules depicted relative to the computer, or portions thereof, may be stored in a remote memory storage device. It will be appreciated that the network connections described or shown are exemplary and other mechanisms of establishing communications over wide area networks or the Internet may be used.

In view of the foregoing detailed description of preferred embodiments of the present invention, it readily will be understood by those persons skilled in the art that the present invention is susceptible to broad utility and application. While various aspects have been described in the context of a preferred embodiment, additional aspects, features, and methodologies of the present invention will be readily discernible from the description herein, by those of ordinary skill in the art. Many embodiments and adaptations of the present invention other than those herein described, as well as many variations, modifications, and equivalent arrangements and methodologies, will be apparent from or reasonably suggested by the present invention and the foregoing description thereof, without departing from the substance or scope of the present invention. Furthermore, any sequence(s) and/or temporal order of steps of various processes described and claimed herein are those considered to be the best mode contemplated for carrying out the present invention. It should also be understood that, although steps of various processes may be shown and described as being in a preferred sequence or temporal order, the steps of any such processes are not limited to being carried out in any particular sequence or order, absent a specific indication of such to achieve a particular intended result. In most cases, the steps of such processes may be carried out in a variety of different sequences and orders, while still falling within the scope of the present inventions. In addition, some steps may be carried out simultaneously.

The embodiments were chosen and described in order to explain the principles of the inventions and their practical application so as to enable others skilled in the art to utilize the inventions and various embodiments and with various modifications as are suited to the particular use contemplated. Alternative embodiments will become apparent to those skilled in the art to which the present inventions pertain without departing from their spirit and scope. Accordingly, the scope of the present inventions is defined by the appended claims rather than the foregoing description and the exemplary embodiments described therein.

What is claimed is:

1. A method for analyzing energy efficiency of a structure, comprising the steps of:
providing a temperature monitoring device within the structure, wherein the temperature monitoring device is capable of sensing temperature measurements according to a predetermined time interval;
receiving a plurality of indoor temperature measurements associated with the interior of the structure from the temperature monitoring device for a predetermined time period at the predetermined time interval;
receiving a plurality of external temperature measurements obtained from the exterior of the structure;
determining an average indoor temperature and an average external temperature for the predetermined time period based on the received plurality of indoor temperature measurements and received plurality of external temperature measurements, respectively;
determining a rate of change of the plurality of indoor temperature measurements over the predetermined time period; and
determining a performance factor of the structure, wherein the performance factor comprises the rate of change of the plurality of indoor temperature measurements divided by a difference of the average indoor temperature and the average external temperature.

2. The method of claim 1, wherein the performance factor is used to determine the energy efficiency of the structure.

3. The method of claim 1, wherein the temperature monitoring device is physically located in relative proximity to a thermostat associated with energy control of the structure.

4. The method of claim 1, wherein the temperature monitoring device is operatively connected to a thermostat associated with energy control of the structure.

5. The method of claim 1, wherein the rate of change of the plurality of indoor temperature measurements is determined by creating a first regression utilizing a starting temperature, an ending temperature, a plurality of temperatures between the starting temperature and the ending temperature, and the predetermined time period.

6. The method of claim 5, further comprising the steps of:
creating a second regression utilizing a second starting temperature, a second ending temperature, and a plurality of temperatures between the second starting temperature and the second ending temperature;
determining a second rate of change associated with a second predetermined time period; and
identifying an intersection point of the first regression and the second regression.

7. The method of claim 6, wherein the intersection defines the transition between an on cycle and/or an off cycle of an HVAC system associated with the structure.

8. The method of claim 1, wherein the temperature monitoring device is capable of measuring temperatures at a temperature difference of less than or equal to 0.04° F.

9. A system for analyzing energy efficiency of a structure, comprising:
a temperature monitoring device within the structure, wherein the temperature monitoring device is capable of sensing temperature measurements according to a predetermined time interval; and
a processor in operative connection with the temperature monitoring device and operative to:
receive a plurality of indoor temperature measurements associated with the interior of the structure from the temperature monitoring device for a predetermined time period at the predetermined time interval;
receive a plurality of external temperature measurements obtained from the exterior of the structure;
determine an average indoor temperature and an average external temperature for the predetermined time period;
determine a rate of change of the plurality of indoor temperature measurements over the predetermined time period based on the received plurality of indoor temperature measurements and the received plurality of exterior temperature measurements, respectively;
determine a performance factor of the structure, wherein the performance factor comprises the rate of change of the plurality of indoor temperature measurements divided by a difference of the average indoor temperature and the average exterior temperature.

10. The system of claim 9, wherein the performance factor is used to determine the energy efficiency of the structure.

11. The system of claim 9, wherein the temperature monitoring device is operatively connected to a thermostat associated with energy control of the structure.

12. The system of claim 9, wherein the rate of change of a plurality of indoor temperature measurements is determined by creating a first regression utilizing a starting temperature, an ending temperature, a plurality of temperatures between the starting temperature and the ending temperature, and the predetermined time period.

13. The system of claim 12, wherein the processor is further operative to:
creating a second regression utilizing a second starting temperature, a second ending temperature, and a plurality of temperatures in between the second starting temperature and the second ending temperature;
determining a second rate of change associated with a second predetermined time period; and
identifying an intersection point of the first regression and the second regression.

14. The system of claim 13, wherein the intersection point defines the transition between an on cycle and/or off cycle of an HVAC system associated with the structure.

15. The system of claim 9, wherein the temperature monitoring device is capable of measuring temperatures at a temperature difference of less than or equal to 0.04° F.

16. A method for analyzing energy usage in connection with a heating, ventilation, and air conditioning (HVAC) system associated with a structure, wherein by providing a temperature monitoring device is physically located within the structure, wherein the temperature monitoring device is capable of sensing temperature measurements according to a predetermined time interval, comprising the steps of:
receiving a plurality of inside temperature measurements associated with the interior of the structure from the temperature monitoring device for a predetermined time period at the predetermined time interval;
receiving energy usage data for the structure over the predetermined time period, wherein the predetermined time period corresponds to an on or off cycle of the HVAC system;
determining a performance factor for the structure and correlating the building performance factor with the energy usage data for the structure for the predetermined time period to characterize the HVAC system operation.

17. The method of claim 16, wherein correlating the building performance factor with the energy usage data for the structure for the predetermined time period further comprises determining the energy usage per minute for the HVAC system, determining the total HVAC energy usage for the predetermined time period, and determining an impact of the HVAC energy usage on the total energy usage of the structure.

18. The method of claim 16, wherein the temperature monitoring device is operatively connected to a thermostat associated with energy control of the structure.

19. The method of claim 16, wherein the rate of change of a plurality of indoor temperature measurements is determined by creating a first regression utilizing a starting temperature, an ending temperature, a plurality of temperatures between the starting temperature and the ending temperature, and the predetermined time period.

20. The method of claim 19, further comprising the steps of:
creating a second regression utilizing a second starting temperature, a second ending temperature, and a plurality of temperatures between the second starting temperature and the second ending temperature;
determining a second rate of change associated with a second predetermined time period; and
identifying an intersection point of the first regression and the second regression.

21. The method of claim 20, wherein the intersection point defines the transition between an on cycle and/or off cycle of an HVAC cycle associated with the structure.

22. The method of claim 16, wherein the temperature monitoring device is capable of measuring temperatures at a temperature difference of less than or equal to 0.04° F.
